(19) United States
(12) Patent Application Publication
(10) Pub. No.: US 2025/0113536 A1
(43) Pub. Date: Apr. 3, 2025

(54) Display Substrate and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Xiaoxue Wen, Beijing (CN); Taofeng Xie, Beijing (CN); Yuanjie Xu, Beijing (CN); Shuang Li, Beijing (CN); Yulong Wei, Beijing (CN); Zhuangqi Zhou, Beijing (CN)

(21) Appl. No.: 18/728,204

(22) PCT Filed: Jul. 28, 2022
(86) PCT No.: PCT/CN2022/108756

§ 371 Date: Jul. 11, 2024

(51) Int. Cl. H10D 30/67; H10K 59/121; H10K 59/131

(52) U.S. Cl. CPC H10D 30/6734; H10K 59/1213; H10K 59/1315

(57) ABSTRACT

A display substrate includes a plurality of transistors, which includes dual-gate transistors, and further includes a substrate, a semiconductor layer, and a plurality of bridge portions. The semiconductor layer includes active patterns arranged at intervals; at least one active pattern includes an active portion and at least one via hole connection portion that are connected, and a via hole connection portion is located at an end of the active portion; the active portion corresponds to a transistor in the plurality of transistors, and is used to form a channel of the corresponding transistor. Each bridge portion connects via hole connection portions in different active patterns. A dual-gate transistor corresponds to two active patterns, and a bridge portion is connected to via hole connection portions in the two active patterns. A resistivity of a material of the bridge portion is less than that of a material of the semiconductor layer.

### CROSS-REFERENCE TO RELATED APPLICATION

This application is the United States national phase of International Patent Application No. PCT/CN2022/108756, filed Jul. 28, 2022, the disclosure of which is hereby incorporated by reference in its entirety.

### BACKGROUND OF THE INVENTION

### Field of the Invention

The present disclosure relates to the field of display technologies, and in particular, to a display substrate and a display apparatus.

### Description of Related Art

A transistor is a solid semiconductor device that can be used as a variable current switch to control an output current based on an input voltage. The transistors are widely used in display apparatuses. Unlike ordinary mechanical switches, the transistors use electrical signals to control their turn-on and turn-off, so that the switching speed can be very fast.

### SUMMARY OF THE INVENTION

In an aspect, a display substrate is provided. The display substrate includes a plurality of transistors, and the plurality of transistors include dual-gate transistors. The display substrate further includes a substrate, a semiconductor layer and a plurality of bridge portions. The semiconductor layer is located on a side of the substrate. The semiconductor layer includes a plurality of active patterns arranged at intervals; at least one active pattern includes an active portion and at least one via hole connection portion that are connected, and a via hole connection portion is located at an end of the active portion; the active portion corresponds to a transistor in the plurality of transistors, and is used to form a channel of the corresponding transistor. The plurality of bridge portions are located on a side of the semiconductor layer away from the substrate, and each of the plurality of bridge portions connects via hole connection portions in different active patterns. A dual-gate transistor in the dual-gate transistors corresponds to two active patterns, and a bridge portion in the plurality of bridge portions is connected to via hole connection portions in the two active patterns. A resistivity of a material of the bridge portion is less than that of a material of the semiconductor layer.

In some embodiments, the display substrate includes a plurality of pixel driving circuits arranged in columns in a first direction and arranged in rows in a second direction. Each pixel driving circuit includes transistors, and the transistors in the pixel driving circuit include at least one dual-gate transistor in the dual-gate transistors.

In some embodiments, the display substrate further includes at least one gate conductive layer and at least one source-drain electrode layer that are located on the side of the semiconductor layer away from the substrate and are stacked in sequence. The bridge portion is located in a target layer, and the target layer is any layer among the at least one gate conductive layer and the at least one source-drain electrode layer.

In some embodiments, the at least one dual-gate transistor includes a first reset transistor. Two active patterns corresponding to the first reset transistor are a first active pattern and a second active pattern, respectively. The first active pattern and the second active pattern are arranged at an interval in sequence along the first direction and extend along the second direction. The first active pattern includes a first active portion and a first via hole connection portion that are connected, and the first active portion is used to form a channel of the first reset transistor. The second active pattern includes a second active portion and a second via hole connection portion that are connected, and the second active portion is used to form another channel of the first reset transistor. The first via hole connection portion and the second via hole connection portion are arranged in a row along the first direction. The plurality of bridge portions include a first bridge portion extending along the first direction, and the first bridge portion connects the first via hole connection portion and the second via hole connection portion.

In some embodiments, the at least one dual-gate transistor includes a compensation transistor. Two active patterns corresponding to the compensation transistor are a third active pattern and a fourth active pattern, respectively. The third active pattern extends along the first direction, the fourth active pattern extends in the second direction, and extension lines of the third active pattern and the fourth active pattern have an intersection point. The third active pattern includes a third active portion and a third via hole connection portion that are connected. The third via hole connection portion is located at an end of the third active portion close to the intersection point, and the third active portion is used to form a channel of the compensation transistor. The fourth active pattern includes a fourth active portion and a fourth via hole connection portion that are connected. The fourth via hole connection portion is located at an end of the fourth active portion close to the intersection point, and the fourth active portion is used to form another channel of the compensation transistor. The plurality of bridge portions include a second bridge portion, and the second bridge portion connects the third via hole connection portion and the fourth via hole connection portion.

In some embodiments, the at least one dual-gate transistor includes the first reset transistor and the compensation transistor. The second active pattern further includes a fifth via hole connection portion connected to the second active portion, and the fifth via hole connection portion is located at an end of the second active portion away from the second via hole connection portion. The third active pattern corresponding to the compensation transistor further includes a sixth via hole connection portion connected to the third active portion, and the sixth via hole connection portion is located at an end of the third active portion away from the third via hole connection portion. The plurality of bridge portions further include a third bridge portion, and the third bridge portion is connected to the fifth via hole connection portion and the sixth via hole connection portion.

In some embodiments, in the first direction, the third active portion is located between the fourth active portion of the compensation transistor and the first active portion, and the second active portion is located on a side of the first active portion away from the third active portion. In the second direction, the third active portion is located between the fourth active portion and the first active portion. An included angle between an extension direction of the third bridge portion and the first direction is an acute angle.

In some embodiments, the transistors in the pixel driving circuit further include a first light-emitting control transistor and a second reset transistor. The plurality of active patterns further include a fifth active pattern and a sixth active pattern; both the fifth active pattern and the sixth active pattern extend along the second direction, and are arranged at an interval in sequence along the second direction. The fifth active pattern includes a fifth active portion and a seventh via hole connection portion that are connected, the seventh via hole connection portion is located at an end of the fifth active portion close to a sixth active portion, and the fifth active portion is used to form a channel of the first light-emitting control transistor. The sixth active pattern includes the sixth active portion and an eighth via hole connection portion that are connected, the eighth via hole connection portion is located at an end of the sixth active portion close to the fifth active portion, and the sixth active portion is used to form a channel of the second reset transistor. The plurality of bridge portions further include a fourth bridge portion extending along the second direction, and the fourth bridge portion is connected to the seventh via hole connection portion and the eighth via hole connection portion.

In some embodiments, the at least one dual-gate transistor includes the compensation transistor. The fifth active pattern, the sixth active pattern and the fourth active pattern corresponding to the compensation transistor are arranged at intervals in sequence along the second direction, and the fifth active pattern is connected to the fourth active pattern.

In some embodiments, the fourth active pattern further includes a ninth via hole connection portion connected to the fourth active portion, and the ninth via hole connection portion is located at an end of the fourth active portion close to the fifth active portion. The fifth active pattern further includes a tenth via hole connection portion connected to the fifth active portion, and the tenth via hole connection portion is located at an end of the fifth active portion close to the fourth active portion. The plurality of bridge portions further include a fifth bridge portion extending along the second direction, and the fifth bridge portion connects the ninth via hole connection portion and the tenth via hole connection portion.

In some embodiments, the sixth active pattern corresponding to the second reset transistor in a pixel driving circuit in an i-th row and j-th column, and the first active pattern and the second active pattern corresponding to the first reset transistor in a pixel driving circuit in an (i+1)-th row and j-th column are arranged at intervals in sequence along the first direction, where i and j are both positive integers. The at least one gate conductive layer includes a plurality of reset signal lines extending along the first direction and arranged at intervals in sequence along the second direction; a reset signal line in the plurality of reset signal lines covers the sixth active portion of the sixth active pattern corresponding to the second reset transistor in the pixel driving circuit in the i-th row and j-th column, and the first active portion of the first active pattern and the second active portion of the second active pattern corresponding to the first reset transistor in the pixel driving circuit in the (i+1)-th row and j-th column.

In some embodiments, the sixth active pattern further includes an eleventh via hole connection portion connected to the sixth active portion, and the eleventh via hole connection portion is located at an end of the sixth active portion away from the eighth via hole connection portion. The first active pattern further includes a twelfth via hole connection portion connected to the first active portion, and the twelfth via hole connection portion is located at an end of the first active portion away from the first via hole connection portion. The at least one gate conductive layer further includes a plurality of first initial signal lines and a plurality of second initial signal lines extending along the first direction and arranged at intervals in sequence along the second direction, and the plurality of first initial signal lines and the plurality of second initial signal lines are arranged alternately. A first initial signal line in the plurality of first initial signal lines is connected to twelfth via hole connection portions of first active patterns corresponding to first reset transistors in pixel driving circuits in an i-th row. A second initial signal line in the plurality of second initial signal lines is connected to eleventh via hole connection portions of sixth active patterns corresponding to second reset transistors in the pixel driving circuits in the i-th row.

In some embodiments, the at least one gate conductive layer includes two gate conductive layers, and the two gate conductive layers are a first gate conductive layer adjacent to the semiconductor layer and a second gate conductive layer located on a side of the first gate conductive layer away from the semiconductor layer. The reset signal line is located in the first gate conductive layer, and the first initial signal line and the second initial signal line are located in the second gate conductive layer.

In some embodiments, the transistors in the pixel driving circuit further include a driving transistor. The plurality of active patterns further include a seventh active pattern, and a shape of the seventh active pattern is curved. The seventh active pattern and the fourth active pattern are located on a same side of the fifth active pattern along the first direction, and the seventh active pattern is located between the fourth active pattern and the fifth active pattern along the second direction. The seventh active pattern includes a seventh active portion and a thirteenth via hole connection portion that are connected; the thirteenth via hole connection portion is located at an end of the seventh active portion close to the fifth active portion, and the seventh active portion is used to form a channel of the driving transistor. The fifth bridge portion is further connected to the thirteenth via hole connection portion.

In some embodiments, the transistors in the pixel driving circuit further include a switching transistor and a second light-emitting control transistor. The plurality of active patterns further include an eighth active pattern and a ninth active pattern; both the eighth active pattern and the ninth active pattern extend along the second direction, and are arranged at an interval in sequence along the second direction. The eighth active pattern includes an eighth active portion and a fourteenth via hole connection portion that are connected, the fourteenth via hole connection portion is located at an end of the eighth active portion close to a ninth active portion, and the eighth active portion is used to form a channel of the switching transistor. The ninth active pattern includes the ninth active portion and a fifteenth via hole connection portion that are connected, the fifteenth via hole connection portion is located at an end of the ninth active portion close to the eighth active portion, and the ninth active portion is used to form a channel of the second light-emitting control transistor. The plurality of bridge portions further include a sixth bridge portion extending along the second direction, and the sixth bridge portion is connected to the fourteenth via hole connection portion and the fifteenth via hole connection portion.

In some embodiments, in a case where the transistors in the pixel driving circuit further include the pixel driving circuit, the seventh active pattern corresponding to the driving transistor further includes a sixteenth via hole connection portion connected to the seventh active portion, and the sixteenth via hole connection portion is located at an end of the seventh active portion close to the ninth active portion. The sixteenth via hole connection portion is further connected to the sixth bridge portion.

In some embodiments, the at least one gate conductive layer includes a plurality of enable signal lines and a plurality of gate lines extending along the first direction and arranged at intervals in sequence along the second direction, and the plurality of enable signal lines and the plurality of gate lines are arranged alternately. An enable signal line in the plurality of enable signal lines covers fifth active portions corresponding to first light-emitting control transistors in pixel driving circuits in an i-th row, and ninth active portions corresponding to second light-emitting control transistors in the pixel driving circuits in the i-th row. A gate line in the plurality of gate lines covers third active portions and fourth active portions corresponding to compensation transistors in the pixel driving circuits in the i-th row, and eighth active portions corresponding to switching transistors in the pixel driving circuits in the i-th row. N is a positive integer.

In some embodiments, the at least one gate conductive layer includes two gate conductive layers, and the two gate conductive layers are a first gate conductive layer adjacent to the semiconductor layer and a second gate conductive layer located on a side of the first gate conductive layer away from the semiconductor layer. The enable signal line and the gate line are both located in the first gate conductive layer.

In some embodiments, the eighth active pattern further includes a seventeenth via hole connection portion connected to the eighth active portion, and the seventeenth via hole connection portion is located at an end of the eighth active portion away from the fourteenth via hole connection portion. The ninth active pattern further includes an eighteenth via hole connection portion connected to the ninth active portion, and the eighteenth via hole connection portion is located at an end of the ninth active portion away from the fifteenth via hole connection portion. The at least one source-drain electrode layer includes two source-drain electrode layers, and the two source-drain electrode layers are a first source-drain electrode layer and a second source-drain electrode layer located on a side of the first source-drain electrode layer away from the semiconductor layer. The first source-drain electrode layer includes a plurality of power supply voltage signal lines extending along the second direction and arranged at intervals in sequence along the first direction; the second source-drain electrode layer includes a plurality of data lines extending along the second direction and arranged at intervals in sequence along the first direction; and the plurality of power supply voltage signal lines and the plurality of data lines are arranged alternately. A power supply voltage signal line in the plurality of power supply voltage signal lines overlaps pixel driving circuits in a j-th column, and the power supply voltage signal line is electrically connected to eighteenth via hole connection portions of ninth active patterns corresponding to second light-emitting control transistors in pixel driving circuits in the j-th column. A data line in the plurality of data lines is located between two adjacent columns of pixel driving circuits, and the data line is electrically connected to seventeenth via hole connection portions of eighth active patterns corresponding to switching transistors in the pixel driving circuits in the j-th column. j is a positive integer.

In another aspect, a display apparatus is provided. The display apparatus includes the display substrate according to any of the embodiments described above.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings to be described below may be regarded as schematic diagrams, and are not limitations on actual sizes of products involved in the embodiments of the present disclosure.

FIG. 1 is a structural diagram of a display apparatus, in accordance with some embodiments of the present disclosure;

FIG. 2 is a structural diagram of a display substrate, in accordance with some embodiments of the present disclosure;

FIG. 3 is a structural diagram of another display substrate, in accordance with some embodiments of the present disclosure;

FIG. 4 is an equivalent circuit diagram of a pixel driving circuit, in accordance with some embodiments of the present disclosure;

FIG. 5 is a structural diagram of some film layers in a display substrate in an implementation;

FIG. 6a is a schematic diagram of an electrostatic breakdown in an implementation;

FIG. 6b is a schematic diagram of another electrostatic breakdown in an implementation;

FIG. 7a is a structural diagram of yet another display substrate, in accordance with some embodiments of the present disclosure;

FIG. 7b is a structural diagram of a semiconductor layer in the display substrate shown in FIG. 7a;

FIG. 7c is a structural diagram of a first gate conductive layer in the display substrate shown in FIG. 7a;

FIG. 7d is a structural diagram of a semiconductor layer and a first gate conductive layer in the display substrate shown in FIG. 7a;

FIG. 7e is a structural diagram of a second gate conductive layer in the display substrate shown in FIG. 7a;

FIG. 7f is a structural diagram of a first source-drain electrode layer in the display substrate shown in FIG. 7a;

FIG. 7g is a structural diagram of a second source-drain electrode layer in the display substrate shown in FIG. 7a;

FIG. 8a is a structural diagram of yet another display substrate, in accordance with some embodiments of the present disclosure;

FIG. 8b is a sectional view of the display substrate shown in FIG. 8a taken along the direction AA;

FIG. 8c is a structural diagram of a semiconductor layer in the display substrate shown in FIG. 8a;

FIG. 8d is a structural diagram of a first gate conductive layer in the display substrate shown in FIG. 8a;

FIG. 9a is a structural diagram of yet another display substrate, in accordance with some embodiments of the present disclosure;

FIG. 9b is a sectional view of the display substrate shown in FIG. 9a taken along the direction BB;

FIG. 9c is a structural diagram of a semiconductor layer in the display substrate shown in FIG. 9a;

FIG. 9d is a structural diagram of a first gate conductive layer in the display substrate shown in FIG. 9a;

FIG. 10a is a structural diagram of yet another display substrate, in accordance with some embodiments of the present disclosure;

FIG. 10b is a sectional view of the display substrate shown in FIG. 10a taken along the direction CC;

FIG. 10c is a structural diagram of a semiconductor layer in the display substrate shown in FIG. 10a;

FIG. 10d is a structural diagram of a first gate conductive layer in the display substrate shown in FIG. 10a;

FIG. 11a is a structural diagram of yet another display substrate, in accordance with some embodiments of the present disclosure;

FIG. 11b is a sectional view of the display substrate shown in FIG. 11a taken along the direction DD;

FIG. 11c is a structural diagram of a semiconductor layer in the display substrate shown in FIG. 11a;

FIG. 11d is a structural diagram of a first gate conductive layer in the display substrate shown in FIG. 11a;

FIG. 12a is a structural diagram of yet another display substrate, in accordance with some embodiments of the present disclosure;

FIG. 12b is a sectional view of the display substrate shown in FIG. 12a taken along the direction EE;

FIG. 12c is a structural diagram of a first gate conductive layer in the display substrate shown in FIG. 12a;

FIG. 12d is a structural diagram of a second source-drain electrode layer in the display substrate shown in FIG. 12a;

FIG. 13a is a structural diagram of yet another display substrate, in accordance with some embodiments of the present disclosure;

FIG. 13b is a sectional view of the display substrate shown in FIG. 13a taken along the direction FF;

FIG. 13c is a structural diagram of a semiconductor layer in the display substrate shown in FIG. 13a;

FIG. 13d is a structural diagram of a first gate conductive layer in the display substrate shown in FIG. 13a;

FIG. 14a is a structural diagram of yet another display substrate, in accordance with some embodiments of the present disclosure;

FIG. 14b is a sectional view of the display substrate shown in FIG. 14a taken along the direction GG;

FIG. 14c is a structural diagram of a semiconductor layer in the display substrate shown in FIG. 14a;

FIG. 14d is a structural diagram of a first gate conductive layer in the display substrate shown in FIG. 14a;

FIG. 14e is a structural diagram of a second source-drain electrode layer in the display substrate shown in FIG. 14a;

FIG. 15a is a structural diagram of yet another display substrate, in accordance with some embodiments of the present disclosure;

FIG. 15b is a structural diagram of a second source-drain electrode layer in the display substrate shown in FIG. 15a;

FIG. 16a is a structural diagram of yet another display substrate, in accordance with some embodiments of the present disclosure;

FIG. 16b is a structural diagram of a first gate conductive layer in the display substrate shown in FIG. 16a;

FIG. 16c is a structural diagram of a second source-drain electrode layer in the display substrate shown in FIG. 16a;

FIG. 17 is another sectional view of the display substrate shown in FIG. 12a taken along the direction EE;

FIG. 18 is an equivalent circuit diagram of another pixel driving circuit, in accordance with some embodiments;

FIG. 19a is a structural diagram of yet another display substrate, in accordance with some embodiments of the present disclosure;

FIG. 19b is a sectional view of the display substrate shown in FIG. 19a taken along the direction HH;

FIG. 19c is a structural diagram of a semiconductor layer in the display substrate shown in FIG. 19a;

FIG. 19d is a structural diagram of a first gate conductive layer in the display substrate shown in FIG. 19a;

FIG. 19e is a structural diagram of an oxide semiconductor layer in the display substrate shown in FIG. 19a;

FIG. 19f is a structural diagram of a second gate conductive layer in the display substrate shown in FIG. 19a;

FIG. 19g is a structural diagram of a third gate conductive layer in the display substrate shown in FIG. 19a;

FIG. 19h is a structural diagram of some film layers in the display substrate shown in FIG. 19a;

FIG. 19i is a structural diagram of a first source-drain electrode layer in the display substrate shown in FIG. 19a; and

FIG. 19j is a structural diagram of a second source-drain electrode layer in the display substrate shown in FIG. 19a.

### DESCRIPTION OF THE INVENTION

The technical solutions in some embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, the term such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the term “connected” and its derivatives may be used. For example, the term “connected” may be used in the description of some embodiments to indicate that two or more components are in direct physical or electrical contact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or values exceeding those stated.

It should be understood that, in a case that a layer or element is referred to be on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in the apparatuses, and are not intended to limit the scope of the exemplary embodiments.

In circuit structures (e.g., pixel driving circuits) provided in embodiments of the present disclosure, transistors used in the circuit structures may be thin film transistors (TFTs), field effect transistors (FETs, e.g., metal oxide semiconductor FET (MOS-FET)), or other switching devices with same properties, and the embodiments of the present disclosure are described by taking the thin film transistors as an example.

In the circuit structures provided in the embodiments of the present disclosure, a first electrode of each transistor used is one of a source and a drain, and a second electrode of each transistor is the other one of the source and the drain. Since the source and the drain of the transistor may be symmetric in structure, the source and the drain may be indistinguishable in structure. That is, the first electrode and the second electrode of the transistor in the embodiments of the present disclosure may be indistinguishable in structure. For example, in a case where the transistor is a P-type transistor, the first electrode of the transistor is the source, and the second electrode of the transistor is the drain. For example, in a case where the transistor is an N-type transistor, the first electrode of the transistor is the drain, and the second electrode of the transistor is the source.

In the circuit structures provided in the embodiments of the present disclosure, the first node, the second node and other nodes do not represent actual components, but rather represent junctions of related connections in circuit diagrams. That is, these nodes are nodes that are equivalent by junctions of related connections in the circuit diagrams.

Transistors included in the circuit structures provided in the embodiments of the present disclosure may all be N-type transistors or P-type transistors, or a part of the transistors may be N-type transistors and another part of the transistors may be P-type transistors. In the embodiments of the present disclosure, an “effective level” refers to a level that enables a transistor to be turned on. The P-type transistor may be turned on under control of a low-level signal, and the N-type transistor may be turned on under control of a high-level signal.

Some embodiments of the present disclosure provide a display substrate and a display apparatus, and the display substrate 100 and the display apparatus 1000 are respectively described below with reference to the drawings.

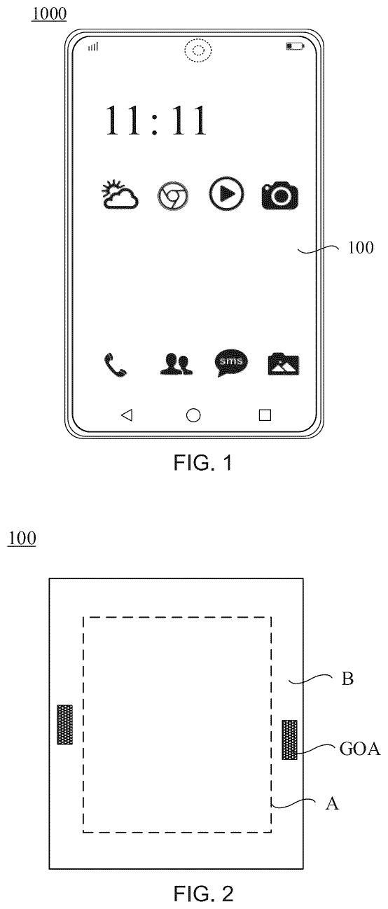

As shown in FIG. 1, some embodiments of the present disclosure provide the display apparatus 1000. The display apparatus 1000 may be any apparatus that displays an image whether in motion (e.g., a video) or stationary (e.g., a still image), and whether literal or graphical. More specifically, it is contemplated that the embodiments may be implemented in or associated with a plurality of electronic devices. The plurality of electronic devices may include (but is not limited to), for example, mobile telephones, wireless devices, personal data assistants (PADs), hand-held or portable computers, global positioning system (GPS) receivers/navigators, cameras, MPEG-4 Part 14 (MP4) video players, video cameras, game consoles, watches, clocks, calculators, TV monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as displays for images of a piece of jewelry).

In some examples, the display apparatus 1000 includes a frame, and the display substrate 100, a circuit board, a data driver integrated circuit (IC) and other electronic accessories that are disposed in the frame.

The display substrate 100 may be, for example, a liquid crystal display (LCD) substrate, or an organic light-emitting diode (OLED) display substrate, which is not specifically limited in the present disclosure.

Some embodiments of the present disclosure will be schematically described below by taking an example in which the display substrate 100 is the OLED display substrate.

As shown in FIG. 2, the display substrate 100 has a display area A and a bezel area B. For example, the bezel area B surrounds the display area A.

For example, the display area A refers to an area of the display substrate 100 used for displaying images. For example, a shape of the display area A may vary, which may be set according to actual needs, and the present disclosure does not limit thereto.

For example, the display area A may be in a shape of a rectangle, approximate rectangle, circle, or ellipse. The approximate rectangle is a rectangle in a non-strict sense, and its four inner corners may be, for example, rounded corners, or a certain side may not be, for example, a straight line.

For convenience of description, the embodiments of the present disclosure are described by taking an example in which the shape of the display area A is rectangular.

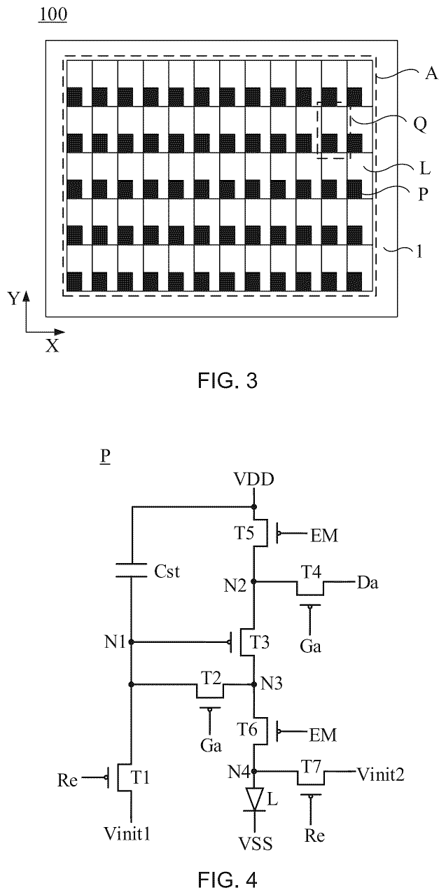

For example, as shown in FIG. 3, the array substrate 100 includes a substrate 1.

A type of the substrate 1 may vary, which may be set according to actual needs.

For example, the substrate 1 may be a rigid substrate. A material of the rigid substrate may include, for example, glass, quartz, plastic, or the like.

For example, the substrate 1 may be a flexible substrate. A material of the flexible substrate may include, for example, polyethylene terephthalate (PET), polyethylene naphthalate two formic acid glycol ester (PEN), polyimide (PI), or the like.

In some examples, a plurality of sub-pixels Q are provided in the display area A. Each sub-pixel Q includes a pixel driving circuit P and a light-emitting device L electrically connected thereto. The pixel driving circuit P and the light-emitting device L are disposed on a side of the substrate 1. The pixel driving circuit P is used to provide a driving signal to the light-emitting device L electrically connected to the pixel driving circuit P. The light-emitting device L is used to emit light under control of the driving signal. The light-emitting devices L in the plurality of sub-pixels Q cooperate with each other for emitting light, thereby achieving display functions of the display substrate 100 and the display apparatus 1000.

For example, the pixel driving circuits P and the light-emitting devices L can be connected in a one-to-one correspondence, or one pixel driving circuit P can be connected to multiple light-emitting devices L, or multiple pixel driving circuits P can be connected to one light-emitting device L.

For example, as shown in FIG. 3, one pixel driving circuit P is connected to one light-emitting device L.

For example, the light-emitting device L may be an OLED.

For example, as shown in FIG. 2, a plurality of shift register circuits GOA are provided in the bezel area B. The shift register circuit GOA is used to provide an electrical signal (for example, a gate signal) to the pixel driving circuit P.

In some examples, the display substrate 100 includes a plurality of transistors, and the plurality of transistors may be located in the display area A and/or the bezel area B.

For example, the transistor located in the bezel area B may be used to form the shift register circuit GOA, and the transistor located in the display area A may be used to form the pixel driving circuit P.

A structure of the display substrate 100 will be schematically described below by taking an example in which the plurality of transistors are used to form the pixel driving circuit P.

In some examples, the plurality of pixel driving circuits P located in the display area A are arranged in an array. As shown in FIG. 3, the plurality of pixel driving circuits P are arranged in columns along a first direction X, and are arranged in columns along a second direction Y.

It will be noted that, a structure of the pixel driving circuit P varies, and may be set according to actual needs. For example, the pixel driving circuit P may be of a structure with “3T1C”, “4T1C”, “6T1C”, “7T1C”, “6T2C”, “7T2C” or “8T2C”. Here, a number before “T” represents the number of transistors, “C” represents a storage capacitor, and a number before “C” represents the number of storage capacitors.

The embodiments of the present disclosure are described by taking an example in which the pixel driving circuit P is of the structure with “7T1C”.

The structure and working process of the pixel driving circuit P will be schematically described below with reference to FIG. 4. It will be noted that, seven transistors and one storage capacitor that are included in the pixel driving circuit P may have other connection relationships therebetween, which are not limited to a connection relationship shown in this example.

As shown in FIG. 4, the pixel driving circuit P includes: a first reset transistor T1, a compensation transistor T2, a driving transistor T3, a switching transistor T4, a second light-emitting control transistor T5, a first light-emitting control transistor T6, a second reset transistor T7 and a storage capacitor Cst. These transistors are all, for example, P-type transistors.

It can be understood that, in the working process of the pixel driving circuit P, a variety of signal lines are required to provide respective electrical signals. Based on this, for example, the display substrate 100 further includes: a reset signal line Re for providing a reset signal, a first initial signal line Vinit1 for providing a first initial signal, a second initial signal line Vinit2 for providing a second initial signal, an enable signal line EM for providing an enable signal, a gate line Ga for providing a gate signal, a power supply voltage signal line VDD for providing a power supply voltage signal, and a data line Da for providing a data signal.

In some examples, a gate of the first reset transistor T1 is electrically connected to the reset signal line Re, a first electrode of the first reset transistor T1 is electrically connected to the first initial signal line Vinit1, and a second electrode of the first reset transistor T1 is electrically connected to a first node N1.

For example, the first reset transistor T1 is configured to transmit the first initial signal received at the first initial signal line Vinit1 to the first node N1 under control of the reset signal transmitted by the reset signal line Re, so as to reset the first node N1.

In some examples, a gate of the second reset transistor T7 is electrically connected to the reset signal line Re, a first electrode of the second reset transistor T7 is electrically connected to the second initial signal line Vinit2, and a second electrode of the second reset transistor T7 is electrically connected to a fourth node N4.

For example, the second reset transistor T7 is configured to transmit the second initial signal received at the second initial signal line Vinit2 to the fourth node N4 under the control of the reset signal, so as to reset the fourth node N4.

In some examples, a gate of the switching transistor T4 is electrically connected to the gate line Ga, a first electrode of the switching transistor T4 is electrically connected to the data line Da, and a second electrode of the switching transistor T4 is electrically connected to a second node N2.

For example, the switching transistor T4 is configured to be turned on under control of the gate signal transmitted by the gate line Ga, and transmit the data signal received at the data line Da to the second node N2.

In some examples, a gate of the driving transistor T3 is electrically connected to the first node N1, a first electrode of the driving transistor T3 is electrically connected to the second node N2, and a second electrode of the driving transistor T3 is electrically connected to a third node N3.

For example, the driving transistor T3 is configured to be turned on under control of the voltage of the first node N1, and transmit the electrical signal (e.g., the data signal) from the second node N2 to the third node N3.

In some examples, a gate of the compensation transistor T2 is electrically connected to the gate line Ga, a first electrode of the compensation transistor T2 is electrically connected to the first node N1, and a second electrode of the compensation transistor T2 is electrically connected to the third node N3.

For example, the compensation transistor T2 is configured to be turned on under the control of the gate signal, and transmit the electrical signal (e.g., the data signal) from the third node N3 to the first node N1.

In some examples, a gate of the second light-emitting control transistor T5 is electrically connected to the enable signal line EM, a first electrode of the second light-emitting control transistor T5 is electrically connected to the power supply voltage signal line VDD, and a second electrode of the second light-emitting control transistor T5 is electrically connected to the second node N2.

For example, the second light-emitting control transistor T5 is configured to be turned on under control of the enable signal transmitted by the enable signal line EM, and transmit the power supply voltage signal received at the power supply voltage signal line VDD to the second node N2.

In some examples, a gate of the first light-emitting control transistor T6 is electrically connected to the enable signal line EM, a first electrode of the first light-emitting control transistor T6 is electrically connected to the third node N3, and a second electrode of the first light-emitting control transistor T6 is electrically connected to the fourth node N4.

For example, the first light-emitting control transistor T6 is configured to be turned on under the control of the enable signal, and transmit the electrical signal from the third node N3 to the fourth node N4.

In some examples, a first electrode of the storage capacitor Cst is electrically connected to the first node N1, and a second electrode of the storage capacitor Cst is electrically connected to the power supply voltage signal line VDD.

For example, the storage capacitor Cst is configured to maintain the voltage of the first node N1 when the first reset transistor T1 and the compensation transistor T2 are turned off.

For example, the display substrate further includes a common voltage line VSS.

For example, the light-emitting device L is electrically connected to the fourth node N4, and the light-emitting device L is further electrically connected to the common voltage line VSS. The light-emitting device L is configured to emit light under control of the electrical signal from the fourth node N4 and the common voltage signal from the common voltage line VSS.

For example, the working process of the pixel driving circuit P includes a reset phase, a data writing and compensation phase, and a light-emitting phase that are performed in sequence.

For example, in the reset phase, under the control of the reset signal, the first reset transistor T1 is turned on, and the first initial signal is transmitted to the first node N to reset the first node N. Since the first node N1 is electrically connected to the first electrode of the storage capacitor Cst, the gate of the driving transistor T3 and the first electrode of the compensation transistor T2, when the first node N1 is reset, the first electrode of the storage capacitor Cst, the gate of the driving transistor T3 and the first electrode of the compensation transistor T2 can be synchronously reset. At the same time, under the control of the reset signal, the second reset transistor T7 is turned on, and the second reset transistor T7 transmits the second initial signal to the fourth node N4 to reset the fourth node N4. The driving transistor T3 can be turned on under control of the first initial signal.

For example, in the data writing and compensation phase, the switching transistor T4 and the compensation transistor T2 are turned on at the same time under the control of the gate signal. The switching transistor T4 transmits the data signal to the second node N2, and the driving transistor T3 transmits the data signal from the second node N2 to the third node N3. The compensation transistor T2 transmits the data signal from the third node N3 to the first node N1 to charge the driving transistor T3 until compensation of the threshold voltage of the driving transistor T3 is completed.

For example, in the light-emitting phase, the first light-emitting control transistor T6 and the second light-emitting control transistor T5 are turned on at the same time under the control of the enable signal. The second light-emitting control transistor T5 transmits the power supply voltage signal to the second node N2. The driving transistor T3 transmits the power supply voltage signal from the second node N2 to the third node N3. The first light-emitting control transistor T6 transmits the voltage signal from the third node N3 to the fourth node N4.

For example, under the action of the driving signal from the fourth node N4 (e.g., the power supply voltage signal) and the common voltage signal from the common voltage line VSS, a driving current can be generated, and the light-emitting device L can emit light under the action of the driving current.

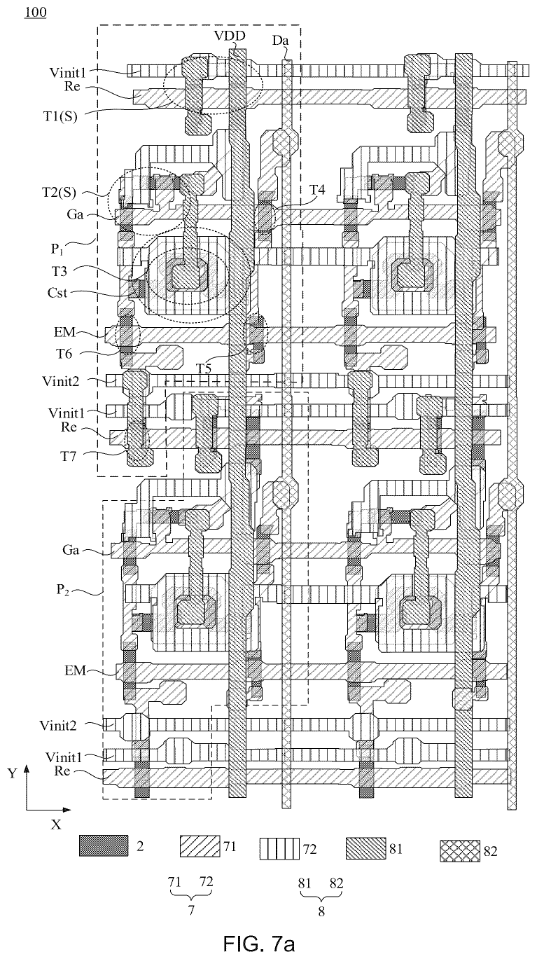

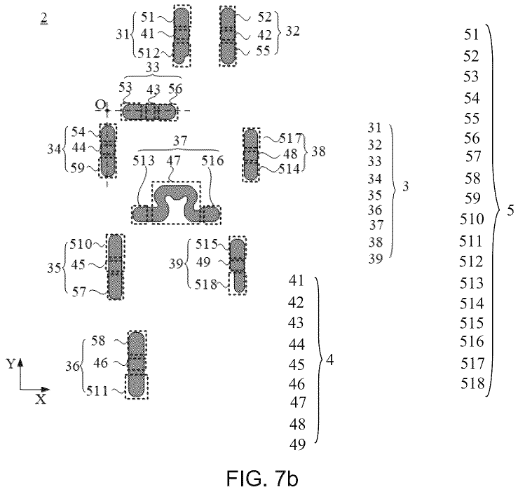

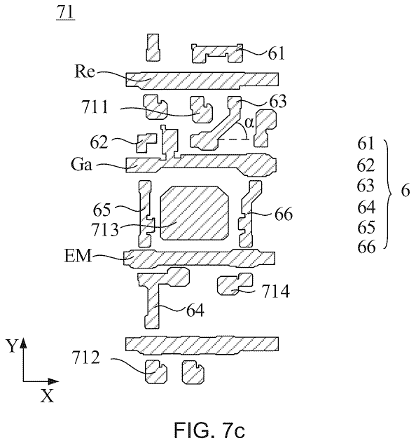

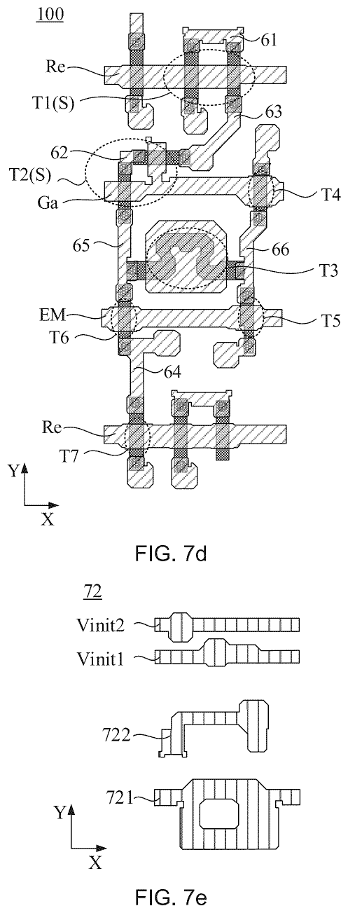

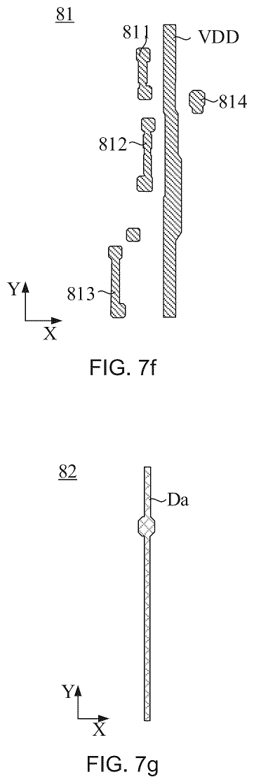

Some embodiments of the present disclosure provide a top view structure of the pixel driving circuit P. As shown in FIG. 7a, in the display substrate 100, in the first direction X, the first light-emitting control transistor T6 and the second light-emitting control transistor T5 are arranged in the same row, and the compensation transistor T2 and the switching transistor T4 are arranged in the same row. In the second direction Y, the compensation transistor T2, the first light-emitting control transistor T6 and the second reset transistor T7 are arranged in the same column, the first reset transistor T1 and the driving transistor T3 are arranged in the same column, and the switching transistor T4 and the second light-emitting control transistor T5 are arranged in the same column. Along the first direction X, the driving transistor T3 is located between the compensation transistor T2 and the switching transistor T4. Along the second direction Y, the driving transistor T3 is located between the compensation transistor T2 and the first light-emitting control transistor T6, and the compensation transistor T2 is located between the first reset transistor T1 and the driving transistor T3.

A position of the storage capacitor Cst overlaps the driving transistor T3, and the storage capacitor Cst is located on a side of the driving transistor T3 away from the substrate 1.

It should be noted that the position of the storage capacitor Cst overlapping the driving transistor T3 means that there is an overlapping region between an orthographic projection of the storage capacitor Cst on the substrate 1 and an orthographic projection of the driving transistor T3 on the substrate 1.

It can be understood that, since the gates of the first light-emitting control transistor T6 and the second light-emitting control transistor T5 are both electrically connected to the enable signal line EM, by arranging the first light-emitting control transistor T6 and the second light-emitting control transistor T5 in the same row, the first light-emitting control transistor T6 and the second light-emitting control transistor T5 in the same pixel driving circuit P may share the same enable signal line EM, which reduces the number of enable signal lines EM and simplifies the structure of the display substrate 100.

It can be understood that, since the gates of the compensation transistor T2 and the switching transistor T4 are both electrically connected to the gate line Ga, by arranging the compensation transistor T2 and the switching transistor T4 in the same row, the compensation transistor T2 and the switching transistor T4 in the same pixel driving circuit P may share the same gate line Ga, which reduces the number of gate lines Ga and simplifies the structure of the display substrate 100.

It can be understood that, along the second direction Y, the compensation transistor T2, the first light-emitting control transistor T6 and the second reset transistor T7 are arranged in the same column, the first reset transistor T1 and the driving transistor T3 are arranged in the same column, and the switching transistor T4 and the second light-emitting control transistor T5 are arranged in the same column, which may make the structure of the transistors in the pixel driving circuit P more compact, thereby reducing the space of the display substrate 100 occupied by the pixel driving circuit P.

It can be understood that, the driving transistor T3 is arranged between the compensation transistor T2 and the switching transistor T4 along the first direction X, and the driving transistor T3 is arranged between the compensation transistor T2 and first light-emitting control transistor T6 along the second direction Y, so that the driving transistor T3 may be arranged in gaps between the above transistors. Therefore, the structure of the pixel driving circuit P is more compact and the space of the display substrate 100 occupied by the pixel driving circuit P is reduced.

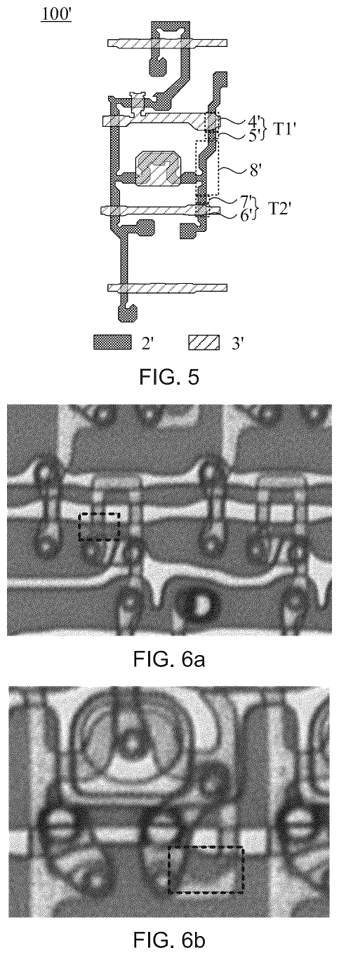

In one implementation, as shown in FIG. 5, a display substrate 100′ includes a semiconductor layer 2′ and a gate conductive layer 3′ that are located on a side of the substrate and are stacked in sequence. An orthographic projection of the semiconductor layer 2′ on the substrate overlaps an orthographic projection of the gate conductive layer 3′ on the substrate. After the gate conductive layer 3′ is formed on a side of the semiconductor layer 2′ away from the substrate, the gate conductive layer 3′ can be used as a mask to perform doping treatment on the semiconductor layer 2′, so that portions of the semiconductor layer 2′ that are not covered by the gate conductive layer 3′ form conductors. A conductor can constitute the first electrode or the second electrode of a transistor. A portion of the semiconductor layer 2′ covered by the gate conductive layer 3′ constitutes a channel of the transistor. A portion of the gate conductive layer 3′ overlapping the semiconductor layer 2′ constitutes a gate pattern of the transistor, and the gate pattern constitutes the gate of the transistor. Some transistors are connected through a semiconductor connection pattern between the transistors.

For example, the transistor T1′ includes a channel 4′ and a first electrode 5′, the transistor T2′ includes a channel 6′ and a first electrode 7′, and the first electrode 5′ of the transistor T1′ is connected to the first electrode 7′ of the transistor T2′ through a semiconductor connection pattern 8′ located between the transistor T1′ and the transistor T2′.

It can be understood that, according to the calculation formula of resistance R=ρL/s, where ρ represents the resistivity of the resistor, L represents the length of the resistor, and S represents the cross-sectional area of the resistor, in a case where values of L and S are the same, the resistance R is directly proportional to the resistivity ρ. Since a material of the semiconductor connection pattern 8′ is a semiconductor material and the resistivity of the semiconductor material is relatively large, the resistance of the semiconductor connection pattern 8′ is relatively large (that is, the connection resistance between the transistor T1′ and the transistor T2′ is relatively large). The electrical signal transmitted between the transistor T1′ and the transistor T2′ suffers a large heat loss after passing through the semiconductor connection pattern 8′, which easily affects the transmission efficiency of the electrical signal. In addition, an ion etching process is often used in the manufacturing process of the display substrate 100′ (for example, patterning the semiconductor layer 2′), and the ion etching process will generate static electricity. When the static electricity accumulates to a certain extent, it will be absorbed by an exposed conductor (e.g., the gate conductive layer 3′ in the display substrate 100′). In this case, the static electricity is equivalent to a constant current source. According to the Ohm's law formula U=I×R, the voltage drop increases with the increase of the resistance R of the load. After charges of the static electricity are conducted to the semiconductor layer 2′ with the large resistivity, the voltage drop of the static electricity on the semiconductor layer 2′ is large, which may cause electrostatic breakdown of the semiconductor layer 2′, and affect the normal operation of the display substrate 100′. For example, the electrostatic breakdown is shown in the boxed regions in FIGS. 6a and 6b.

Based on this, as shown in FIG. 7b, the display substrate 100 provided in the embodiments of the present disclosure includes a semiconductor layer 2 located on a side of the substrate 1. The semiconductor layer 2 includes a plurality of active patterns 3 arranged at intervals. At least one active pattern 3 includes an active portion 4 and at least one via hole connection portion 5 that are connected, and a via hole connection portion 5 is located at an end of the active portion 4. The active portion 4 corresponds to a transistor, and is used to form a channel of the corresponding transistor.

For example, a material of the semiconductor layer 2 is a semiconductor material. For example, the semiconductor material is polysilicon.

For example, the via hole connection portion 5 is a portion of the active pattern 3 of the transistor used to connect the bridge portion 6 described below, or the via hole connection portion 5 is a portion of the active pattern 3 of the transistor used to connect a signal line (e.g., a gate line, or a data line).

For example, there are one or two via hole connection portions 5 included in the active pattern 3.

For example, the active pattern 3 is in a shape of a long strip, the number of via hole connection portions 5 is two, and the two via hole connection portions 5 are respectively located at opposite ends of the active portion 4.

In some examples, as shown in FIGS. 7b to 7d, the display substrate 100 further includes a plurality of bridge portions 6 located on a side of the semiconductor layer 2 away from the substrate 1. Each bridge portion 6 connects via hole connection portions 5 in different active patterns 3. The plurality of transistors included in the display substrate 100 include dual-gate transistors S. The dual-gate transistor S corresponds to two active patterns 3, and a bridge portion 6 is connected to the via hole connection portions 5 in the two active patterns 3. The resistivity of the material of the bridge portion 6 is less than that of the material of the semiconductor layer 2.

For example, at least one insulating layer is provided between the bridge portion 6 and the semiconductor layer 2. The insulating layer is used to isolate the bridge portion 6 from the semiconductor layer 2 to avoid short circuit between the bridge portion 6 and the semiconductor layer 2.

For example, the bridge portion 6 is connected to the semiconductor layer 2 through a via hole penetrating through the at least one insulating layer.

By connecting bridge portions 6 to the via hole connection portions 5 in different active patterns 3, different active patterns 3 arranged at intervals may be connected to each other through the bridge portions 6; and by connecting a bridge portion 6 to the via hole connection portions 5 in the two active patterns 3 of the dual-gate transistor S, the two active patterns 3, arranged at an interval, of the dual-gate transistor S are connected to each other through the bridge portion 6. Furthermore, by making the resistivity of the material of the bridge portion 6 less than that of the material of the semiconductor layer 2, compared with the semiconductor connection pattern 8′ in one implementation, the resistance of the bridge portion 6 may be made less than that of the semiconductor connection pattern 8′. Thus, the resistance between different active patterns 3 connected through the bridge portion 6 may be reduced, that is, the connection resistance between different transistors may be reduced and the resistance between the two active patterns 3 of the dual-gate transistor S may be reduced. The heat loss of electrical signals may be reduced when the electrical signals are transmitted between different transistors and between the two active patterns 3 of the dual-gate transistor S, thereby ensuring the transmission efficiency of the electrical signals between different transistors and between the two active patterns 3 of the dual-gate transistor S, and reducing the power consumption of the display substrate 100. Moreover, with the above arrangement, in a case where the static electricity generated during the manufacturing process of the display substrate 100 is conducted to the semiconductor layer 2, the static electricity is also conducted along the bridge portion 6, increasing a discharge path of the static electricity. Since the resistance of the bridge portion 6 is relatively small, the voltage drop of the static electricity on the bridge portion 6 is relatively small, which may reduce the voltage difference between two ends of the semiconductor layer 2, thereby avoiding the electrostatic breakdown of the semiconductor layer 2.

Furthermore, the shape of the bridge portion 6 may be set to be the same as the shape of the semiconductor connection pattern 8′. In this way, it may be possible to avoid adjusting positional relationships between different active patterns 3, avoid greatly changing the layout design of the display substrate 100, and simplify the manufacturing process of the display substrate 100.

In some embodiments, as shown in FIG. 7a, the display substrate 100 further includes at least one gate conductive layer 7 and at least one source-drain electrode layer 8 that are located on the side of the semiconductor layer 2 away from the substrate 1 and are stacked in sequence. The bridge portion 6 is located in a target layer, and the target layer is any layer among the gate conductive layer(s) 7 and the source-drain electrode layer(s) 8.

For example, there is one or two gate conductive layers 7, and there is one or two source-drain electrode layers 8. The target layer represents any layer among the gate conductive layer(s) 7 and the source-drain electrode layer(s) 8. The target layer(s) may be any one layer or any multiple layers among the gate conductive layer(s) 7 and the source-drain electrode layer(s) 8.

In some examples, there are two gate conductive layers 7 and two source-drain electrode layers 8. As shown in FIG. 7a, the gate conductive layer 7 includes a first gate conductive layer 71 and a second gate conductive layer 72, and the source-drain electrode layer 8 includes a first source-drain electrode layer 81 and a second source-drain electrode layer 82.

For example, the bridge portion 6 is located in the first gate conductive layer 71 or the second source-drain electrode layer 82, which is not limited in the present disclosure.

By arranging the bridge portion 6 in the existing film layer of the display substrate 100 without additionally arranging other film layers, it helps avoid increasing the number of film layers included in the display substrate 100 and avoiding increasing the thickness of the display substrate 100.

For example, materials of the gate conductive layer 7 and the source-drain electrode layer 8 are metals or alloy materials with good conductivity. As shown in Table 1, approximate values of the resistivities of different film layers or materials are shown. As can be seen from Table 1 that, in the display substrate 100, the resistivity of the semiconductor layer 2 is the largest, followed by the resistivity of the source-drain electrode layer 8, and the resistivity of the gate conductive layer 7 is the smallest. Therefore, in the case where the bridge portion 6 is located in any layer of the at least one gate conductive layer 7 or at least one source-drain electrode layer 8, the resistivity of the bridge portion 6 may be made less than that of the semiconductor material of the semiconductor layer 2.

TABLE 1

| Item | Resistivity (Ω/m) |
|---|---|
| Semiconductor layer | 2.52*10⁻⁴ |
| Gate conductive layer | 5.17*10⁻¹⁰ |
| Source-drain electrode | 2.9*10⁻⁸ |
| layer | |
| Iron | 1.7*10⁻⁷ |

For example, in the case where the resistivity of the bridge portion 6 is less than the resistivity of the semiconductor layer 2, the resistivity of the bridge portion 6 is less than 2.5*10⁻⁴ Ω/m.

By arranging the bridge portion 6 in the gate conductive layer 7 or the source-drain electrode layer 8, the resistivity of the bridge portion 6 may be made less than that of the semiconductor layer 2, thereby reducing the resistance between different active patterns 3 connected through the bridge portion 6. Therefore, the transmission efficiency of the electrical signals between different transistors and between the two active patterns 3 of the dual-gate transistor S may be ensured, and the power consumption of the display substrate 100 may be reduced. Moreover, with the above arrangement, the voltage drop of the static electricity on the bridge portion 6 is relatively small, which may reduce the voltage difference between two ends of the semiconductor layer 2, thereby avoiding the electrostatic breakdown of the semiconductor layer 2.

It can also be seen from Table 1 that, in the case where the bridge portion 6 is located in the gate conductive layer 7 with the smallest resistivity, the solution of the present disclosure may achieve a better effect of reducing resistance. Optionally, in some embodiments of the present disclosure, all the bridge portions 6 are disposed in the gate conductive layer 7. In this way, the resistance of the bridge portion 6 disposed in the gate conductive layer 7 may be smaller, and the transmission efficiency of the electrical signals between different transistors and between the two active patterns 3 of the dual-gate transistor S may be further ensured, the power consumption of the display substrate 100 may be reduced, and the electrostatic breakdown of the semiconductor layer 2 may be avoided.

In some embodiments, the dual-gate transistor S in the pixel driving circuit P in the embodiments of the present disclosure includes the first reset transistor T1 and/or the compensation transistor T2. That is, the first reset transistor T1 corresponds to two active patterns 3, and the compensation transistor T2 corresponds to two active patterns 3.

In some embodiments, as shown in FIG. 7b, the two active patterns 3 corresponding to the first reset transistor T1 are a first active pattern 31 and a second active pattern 32, respectively. The first active pattern 31 and the second active pattern 32 are arranged at an interval in sequence along the first direction X and extend along the second direction Y. The first active pattern 31 includes a first active portion 41 and a first via hole connection portion 51 that are connected, and the first active portion 41 is used to form a channel of the first reset transistor T1. The second active pattern 32 includes a second active portion 42 and a second via hole connection portion 52 that are connected, and the second active portion 42 is used to form another channel of the first reset transistor T1. The first via hole connection portion 51 and the second via hole connection portion 52 are arranged in a row along the first direction X.

For example, the first active pattern 31 and the second active pattern 32 are arranged at an interval in sequence along the first direction X, which means that the first active pattern 31 and the second active pattern 32 are arranged in a row in the first direction. It should be noted that, considering process accuracy, there may be a certain misalignment between the first active pattern 31 and the second active pattern 32 in the second direction Y.

For example, the first via hole connection portion 51 and the second via hole connection portion 52 are portions connected to each other in the first reset transistor T1.

It should be noted that, considering process accuracy, along the first direction X, the first via hole connection portion 51 and the second via hole connection portion 52 arranged in a row may also have a certain misalignment in the second direction Y.

In some examples, as shown in FIG. 7c, the plurality of bridge portions 6 include a first bridge portion 61 extending along the first direction X. As shown in FIG. 7d, the first bridge portion 61 connects the first via hole connection portion 51 and the second via hole connection portion 52.

For example, an end of the first bridge portion 61 is connected to the first via hole connection portion 51 through a via hole, and the other end of the first bridge portion 61 is connected to the second via hole connection portion 52 through a via hole.

For example, the first bridge portion 61 is in a shape of a long strip.

For example, by arranging the first bridge portion 61 to extend along the first direction X, the length of the first bridge portion 61 may be the smallest, which may save the material of the first bridge portion 61, and reduce the resistance of the first bridge portion 61.

By arranging the first bridge portion 61 between the first active pattern 31 and the second active pattern 32 of the first reset transistor T1, the resistance between the first active pattern 31 and the second active pattern 32 of the first reset transistor T1 may be reduced, thereby improving the transmission efficiency of the electrical signal between the first active pattern 31 and the second active pattern 32, reducing the power consumption of the display substrate 100, and reducing a risk of electrostatic breakdown between the first active pattern 31 and the second active pattern 32.

In some embodiments, as shown in FIG. 7b, the two active patterns 3 corresponding to the compensation transistor T2 are a third active pattern 33 and a fourth active pattern 34, respectively. The third active pattern 33 extends along the first direction X, the fourth active pattern 34 extends in the second direction Y, and extension lines of the third active pattern 33 and the fourth active pattern 34 have an intersection point O. The third active pattern 33 includes a third active portion 43 and a third via hole connection portion 53 that are connected. The third via hole connection portion 53 is located at an end of the third active portion 43 close to the intersection point O. The third active portion 33 is used to form a channel of the compensation transistor T2. The fourth active pattern 34 includes a fourth active portion 44 and a fourth via hole connection portion 54 that are connected. The fourth via hole connection portion 54 is located at an end of the fourth active portion 44 close to the intersection point O. The fourth active portion 44 is used to form another channel of the compensation transistor T2.

For example, the extension lines of the third active pattern 33 and the fourth active pattern 34 have the intersection point O, which means that the extension line of the third active pattern 33 does not overlap with the fourth active pattern 34, and the extension line of the fourth active pattern 34 does not overlap with the third active pattern 33.

For example, the third via hole connection portion 53 and the fourth via hole connection portion 54 are portions connected to each other in the compensation transistor T2.

In some examples, as shown in FIG. 7c, the plurality of bridge portions 6 further include a second bridge portion 62. As shown in FIG. 7d, the second bridge portion 62 connects the third via hole connection portion 53 and the fourth via hole connection portion 54.

For example, as shown in FIGS. 7c and 7d, the second bridge portion 62 is in the shape of a broken line, a part of the second bridge portion 62 extends along the first direction X, and the other part of the second bridge portion 62 extends along the second direction Y; the two parts of the second bridge portion 62 overlap at the intersection point O. With such an arrangement, it may maintain a sufficient gap between the second bridge portion 62 and the gate line Ga, thereby preventing the electrical signal transmitted on the second bridge portion 62 and the electrical signal transmitted on the gate line Ga from interfering with each other.

By arranging the second bridge portion 62 between the third active pattern 33 and the fourth active pattern 34 of the compensation transistor T2, the resistance between the third active pattern 33 and the fourth active pattern 34 of the compensation transistor T2 may be reduced, thereby improving the transmission efficiency of the electrical signal between the third active pattern 33 and the fourth active pattern 34, reducing the power consumption of the display substrate 100, and reducing a risk of electrostatic breakdown between the third active pattern 33 and the fourth active pattern 34.

It should be noted that the first reset transistor T1 and the compensation transistor T2 are connected to each other. It can be understood that the first reset transistor T1 and the compensation transistor T2 can be connected through the semiconductor material located between the first reset transistor T1 and the compensation transistor T2, or the first reset transistor T1 and the compensation transistor T2 can be connected through a bridge portion 6.

In some embodiments, as shown in FIG. 7b, the second active pattern 32 further includes a fifth via hole connection portion 55 connected to the second active portion 42, and the fifth via hole connection portion 55 is located at an end of the second active portion 42 away from the second via hole connection portion 52. The third active pattern 33 corresponding to the compensation transistor T2 further includes a sixth via hole connection portion 56 connected to the third active portion 43. The sixth via hole connection portion 56 is located at an end of the third active portion 43 away from the third via hole connection portion 53.

In some examples, as shown in FIG. 7c, the plurality of bridge portions 6 further include a third bridge portion 63. With reference to FIGS. 7b, 7c, and 7d, the third bridge portion 63 is connected to the fifth via hole connection portion 55 and the sixth via hole connection portion 56.

By arranging the third bridge portion 63 between the second active pattern 32 of the first reset transistor T1 and the third active pattern 33 of the compensation transistor T2, the resistance between the second active pattern 32 and the third active pattern 33 may be reduced, thereby improving the transmission efficiency of the electrical signal between the second active pattern 32 and the third active pattern 33, reducing the power consumption of the display substrate 100, and reducing a risk of electrostatic breakdown between the second active pattern 32 and the third active pattern 33.

In some embodiments, as shown in FIG. 7b, in the first direction X, the third active portion 43 is located between the fourth active portion 44 and the first active portion 41, and the second active portion 42 is located on a side of the first active portion 41 away from the third active portion 43. In the second direction Y, the third active portion 43 is located between the fourth active portion 44 and the first active portion 41. As shown in FIG. 7c, an included angle α between the extension direction of the third bridge portion 63 and the first direction X is an acute angle.

For example, a value of a may be 10°, 30°, 50°, 70°, 85°, or the like.

In some embodiments, as shown in FIG. 7b, the first light-emitting control transistor T6 and the second reset transistor T7 in the pixel driving circuit P are taken as an example, the plurality of active patterns 3 further include a fifth active pattern 35 and a sixth active pattern 36. Both the fifth active pattern 35 and the sixth active pattern 36 extend along the second direction Y, and they are arranged at an interval in sequence along the second direction Y. The fifth active pattern 35 includes a fifth active portion 45 and a seventh via hole connection portion 57 that are connected. The seventh via hole connection portion 57 is located at an end of the fifth active portion 45 close to a sixth active portion 46. The fifth active portion 45 is used to form a channel of the first light-emitting control transistor T6. The sixth active pattern 36 includes the sixth active portion 46 and an eighth via hole connection portion 58 that are connected. The eighth via hole connection portion 58 is located at an end of the sixth active portion 46 close to the fifth active portion 45. The sixth active portion 46 is used to form a channel of the second reset transistor T7.

For example, the fifth active pattern 35 and the sixth active pattern 36 are arranged at an interval in sequence along the second direction Y, which means that the fifth active pattern 35 and the sixth active pattern 36 are arranged in a row in the second direction Y. It should be noted that, considering process accuracy, the fifth active pattern 35 and the sixth active pattern 36 may have a certain misalignment in the first direction X and are not strictly arranged in a row.

In some examples, as shown in FIG. 7c, the plurality of bridge portions 6 further include a fourth bridge portion 64 extending along the second direction Y. With reference to FIGS. 7b, 7c, and 7d, the fourth bridge portion 64 is connected to the seventh via hole connection portion 57 and the eighth via hole connection portion 58.

For example, the fourth bridge portion 64 is in a shape of a long strip, and a long side of the fourth bridge portion 64 is parallel to the second direction Y.

By arranging the fourth bridge portion 64 between the fifth active portion 45 of the first light-emitting control transistor T6 and the sixth active portion 46 of the second reset transistor T7, the resistance between the fifth active portion 45 and the sixth active portion 46 may be reduced, thereby improving the transmission efficiency of the electrical signal between the fifth active portion 45 and the sixth active portion 46, reducing the power consumption of the display substrate 100, and reducing a risk of electrostatic breakdown between the fifth active portion 45 and the sixth active portion 46.

In some embodiments, as shown in FIG. 7b, the fifth active pattern 35, the sixth active pattern 36 and the fourth active pattern 34 corresponding to the compensation transistor T2 are arranged at intervals in sequence along the second direction Y, and the fifth active pattern 35 is connected to the fourth active pattern 34.

For example, the fifth active pattern 35, the sixth active pattern 36 and the fourth active pattern 34 are arranged at intervals in sequence along the second direction Y, which means that the fifth active pattern 35, the sixth active pattern 36 and the fourth active pattern 34 are arranged in a row in the second direction Y. It should be noted that, considering process accuracy, the fifth active pattern 35 and the sixth active pattern 36 may have a certain misalignment in the first direction X and are not strictly arranged in a row.

It can be understood that the fifth active pattern 35 and the fourth active pattern 34 are connected in various ways, for example, they are connected through a bridge portion 6.

In some examples, as shown in FIG. 7b, the fourth active pattern 34 further includes a ninth via hole connection portion 59 connected to the fourth active portion 44, and the ninth via hole connection portion 59 is located at an end of the fourth active portion 44 close to the fifth active portion 45. The fifth active pattern 35 further includes a tenth via hole connection portion 510 connected to the fifth active portion 45, and the tenth via hole connection portion 510 is located at an end of the fifth active portion 45 close to the fourth active portion 44.

As shown in FIG. 7c, the plurality of bridge portions 6 further include a fifth bridge portion 65 extending along the second direction Y. As shown in FIG. 7d, the fifth bridge portion 65 connects the ninth via hole connection portion 59 and the tenth via hole connection portion 510.

For example, the fifth bridge portion 65 is in a shape of a long strip, and a long side of the fifth bridge portion 65 is parallel to the second direction Y.

By arranging the fifth bridge portion 65 between the fourth active portion 44 of the compensation transistor T2 and the fifth active portion 45 of the first light-emitting control transistor T6, the resistance between the fourth active portion 44 and the fifth active portion 45 may be reduced, thereby improving the transmission efficiency of the electrical signal between the fourth active portion 44 and the fifth active portion 45, reducing the power consumption of the display substrate 100, and reducing a risk of electrostatic breakdown between the fourth active portion 44 and the fifth active portion 45.

In some embodiments, as shown in FIG. 7a, the plurality of pixel driving circuits P included in the display substrate 100 include two adjacent pixel driving circuits P along the second direction Y. The two adjacent pixel driving circuits P are, for example, a pixel driving circuit P₁ in the i-th row and j-th column, and a pixel driving circuit P₂ in the (i+1)-th row and j-th column.

The sixth active pattern 36 corresponding to the second reset transistor T7 in the pixel driving circuit P₁ in the i-th row and j-th column, and the first active pattern 31 and the second active pattern 32 corresponding to the first reset transistor T1 in the pixel driving circuit P₂ in the (i+1)-th row and j-th column are arranged at intervals in sequence along the first direction X, where i and j are both positive integers. The at least one gate conductive layer 7 includes a plurality of reset signal lines Re extending along the first direction X and arranged at intervals in sequence along the second direction Y. A reset signal line Re covers the sixth active portion 46 of the sixth active pattern 36 corresponding to the second reset transistor T7 in the pixel driving circuit P₁ in the i-th row and j-th column, and the first active portion 41 of the first active pattern 31 and the second active portion 42 of the second active pattern 32 corresponding to the first reset transistor T1 in the pixel driving circuit P₂ in the (i+1)-th row and j-th column.

For example, the sixth active pattern 36 of the second reset transistor T7 in the pixel driving circuit P₁, and the first active pattern 31 and the second active pattern 32 of the first reset transistor T1 in the pixel driving circuit P₂ are arranged at intervals in sequence along the first direction X, which means that the sixth active pattern 36 of the second reset transistor T7 in the pixel driving circuit P₁, and the first active pattern 31 and the second active pattern 32 of the first reset transistor T1 in the pixel driving circuit P₂ are arranged in a row in the first direction X. It should be noted that, considering process accuracy, there may be a certain misalignment between the sixth active pattern 36 of the second reset transistor T7 in the pixel driving circuit P₁, and the first active pattern 31 and the second active pattern 32 of the first reset transistor T1 in the pixel driving circuit P₂ in the first direction X.

For example, two adjacent pixel driving circuits P located in the same column share one reset signal line Re. For example, the second reset transistor T7 in the pixel driving circuit P₁ and the first reset transistor T1 in the pixel driving circuit P₂ share one reset signal line Re. In this way, the space of the display substrate 100 occupied by the reset signal lines Re may be reduced, and the manufacturing process of the display substrate 100 may be simplified.

By covering the sixth active portion 46 of the sixth active pattern 36 in the second reset transistor T7 with one reset signal line Re, a portion, covered by the reset signal line Re, of the sixth active portion 46 of the sixth active pattern 36 in the second reset transistor T7 may form the gate of the second reset transistor T7. When a corresponding signal is input to the reset signal line Re, the on-off state of the second reset transistor T7 may be controlled. By covering the first active portion 41 of the first active pattern 31 and the second active portion 42 of the second active pattern 32 corresponding to the first reset transistor T1 with one reset signal line Re, portions, covered by the reset signal line Re, of the first active portion 41 and the second active portion 42 that are respectively in the first active pattern 31 and the second active pattern 32 in the first reset transistor T1 may form the gate of the first reset transistor T1. When a corresponding signal is input to the reset signal line Re, the on-off state of the first reset transistor T1 may be controlled.

That is, by arranging one reset signal line Re, the second reset transistor T7 in the pixel driving circuit P₁ and the first reset transistor T1 in the pixel driving circuit P₂ may be controlled simultaneously. Thus, the number of reset signal lines Re in the display substrate 100 may be reduced, the space of the display substrate 100 occupied by the reset signal lines Re may be reduced, and the manufacturing process of the display substrate 100 may be simplified.

In some embodiments, as shown in FIG. 7b, the sixth active pattern 36 further includes an eleventh via hole connection portion 511 connected to the sixth active portion 46, and the eleventh via hole connection portion 511 is located at an end of the sixth active portion 46 away from the eighth via hole connection portion 58. The first active pattern 31 further includes a twelfth via hole connection portion 512 connected to the first active portion 41, and the twelfth via hole connection portion 512 is located at an end of the first active portion 41 away from the first via hole connection portion 51.

The at least one gate conductive layer 7 further includes a plurality of first initial signal lines Vinit1 and a plurality of second initial signal lines Vinit2 extending along the first direction X and arranged at intervals in sequence along the second direction Y, and the first initial signal lines Vinit1 and the second initial signal lines Vinit2 are arranged alternately. A first initial signal line Vinit1 is electrically connected to the twelfth via hole connection portions 512 of the first active patterns 31 corresponding to the first reset transistors T1 in the pixel driving circuits P₁ in the i-th row. A second initial signal line Vinit2 is electrically connected to the eleventh via hole connection portions 511 of the sixth active patterns 36 corresponding to the second reset transistors T7 in the pixel driving circuits P₁ in the i-th row.

For example, the pixel driving circuits P located in the same row share the first initial signal line Vinit1 and the second initial signal line Vinit2. In this way, the space of the display substrate 100 occupied by the first initial signal lines Vinit1 and the second initial signal lines Vinit2 may be reduced, and the manufacturing process of the display substrate 100 may be simplified.

For example, there are various ways for the first initial signal line Vinit1 to be electrically connected to the twelfth via hole connection portion 512 of the first active pattern 31.

For example, the first gate conductive layer 71 includes a first connection pattern 711, and an orthographic projection of the first connection pattern 711 on the substrate 1 overlaps an orthographic projection of the twelfth via hole connection portion 512 on the substrate 1. The first initial signal line Vinit1 is electrically connected to the first connection pattern 711 located in the first gate conductive layer 71 through a via hole, and the first connection pattern 711 is also electrically connected to the twelfth via hole connection portion 512 located in the semiconductor layer 2 through a via hole. Thus, the electrical connection between the first initial signal line Vinit1 and the twelfth via hole connection portion 512 is achieved.

For example, there are various ways for the second initial signal line Vinit2 to be electrically connected to the eleventh via hole connection portion 511 of the sixth active pattern 36.

For example, the first gate conductive layer 71 includes a second connection pattern 712, and an orthographic projection of the second connection pattern 712 on the substrate 1 overlaps an orthographic projection of the eleventh via hole connection portion 511 on the substrate 1. The second initial signal line Vinit2 is electrically connected to the second connection pattern 712 located in the first gate conductive layer 71 through a via hole, and the second connection pattern 712 is also electrically connected to the eleventh via hole connection portion 511 located in the semiconductor layer 2 through a via hole. Thus, the electrical connection between the second initial signal line Vinit2 and the eleventh via hole connection portion 511 is achieved.

By electrically connecting the first initial signal line Vinit1 to the twelfth via hole connection portion 512 of the first active pattern 31 corresponding to the first reset transistor T1 in the pixel driving circuit P₁, the first initial signal transmitted on the first initial signal line Vinit1 may be transmitted to the first reset transistor T1 of the pixel driving circuit P₁. By electrically connecting the second initial signal line Vinit2 to the eleventh via hole connection portion 511 of the sixth active pattern 36 corresponding to the second reset transistor T7 in the pixel driving circuit P₁, the second initial signal transmitted on the second initial signal line Vinit2 may be transmitted to the second reset transistor T7 of the pixel driving circuit P₁.

In some embodiments, as shown in FIG. 7a, in the display substrate 100, the first gate conductive layer 71 is adjacent to the semiconductor layer 2, and the second gate conductive layer 72 is located on a side of the first gate conductive layer 71 away from the semiconductor layer 2. The reset signal lines Re are located in the first gate conductive layer 71, and the first initial signal lines Vinit1 and the second initial signal lines Vinit2 are located in the second gate conductive layer 72.

By arranging the reset signal lines Re in the first gate conductive layer 71 close to the side of the semiconductor layer 2, it is convenient for reset signals transmitted on the reset signal lines Re to control active portions 4 of the transistors T in the semiconductor layer 2. By arranging the reset signal lines Re, the first initial signal lines Vinit1 and the second initial signal lines Vinit2 extending in the same direction in different layers, it is convenient to increase the wiring space.

In some embodiments, as shown in FIG. 7b, the driving transistor T3 in the pixel driving circuit P is taken as an example, the plurality of active patterns 3 further include a seventh active pattern 37, and a shape of the seventh active pattern 37 is curved. The seventh active pattern 37 and the fourth active pattern 34 are located on the same side of the fifth active pattern 35 along the first direction X; the seventh active pattern 37 is located between the fourth active pattern 34 and the fifth active pattern 35 along the second direction Y. The seventh active pattern 37 includes a seventh active portion 47 and a thirteenth via hole connection portion 513 that are connected. The thirteenth via hole connection portion 513 is located at an end of the seventh active portion 47 close to the fifth active portion 45, and the seventh active portion 47 is used to form a channel of the driving transistor T3. As shown in FIGS. 7b, 7c and 7d, the fifth bridge portion 65 is further connected to the thirteenth via hole connection portion 513.

By arranging the seventh active pattern 37 in the curved shape, a length of the seventh active portion 47 of the seventh active pattern 37 may be increased. Thus, the channel of the driving transistor T3 has a large aspect ratio, which is beneficial for the driving transistor T3 to work in the saturation region, and makes the driving transistor T3 output a stable current for driving the light-emitting device L to emit light.

By connecting the fifth bridge portion 65 to the thirteenth via hole connection portion 513, the resistance between the fourth active portion 44, the fifth active portion 45 and the seventh active portion 47 may be reduced, thereby improving the transmission efficiency of the electrical signal between the fourth active portion 44 and the seventh active portion 47 and the transmission efficiency of the electrical signal between the fifth active portion 45 and the seventh active portion 47, reducing the power consumption of the display substrate 100, and reducing a risk of electrostatic breakdown between the fourth active portion 44 and the seventh active portion 47, as well as between the fifth active portion 45 and the seventh active portion 47.

In some embodiments, as shown in FIG. 7b, the switching transistor T4 and the second light-emitting control transistor T5 in the pixel driving circuit P are taken as an example, the plurality of active patterns 3 further include an eighth active pattern 38 and a ninth active pattern 39. Both the eighth active pattern 38 and the ninth active pattern 39 extend along the second direction Y, and they are arranged at an interval in sequence along the second direction Y. The eighth active pattern 38 includes an eighth active portion 48 and a fourteenth via hole connection portion 514 that are connected, and the fourteenth via hole connection portion 514 is located at an end of the eighth active portion 48 close to a ninth active portion 49. The eighth active portion 48 is used to form a channel of the switching transistor T4. The ninth active pattern 39 includes the ninth active portion 49 and a fifteenth via hole connection portion 515 that are connected, and the fifteenth via hole connection portion 515 is located at an end of the ninth active portion 49 close to the eighth active portion 48. The ninth active portion 49 is used to form a channel of the second light-emitting control transistor T5. As shown in FIGS. 7c and 7d, the plurality of bridge portions 6 further include a sixth bridge portion 66 extending along the second direction Y, and the sixth bridge portion 66 is connected to the fourteenth via hole connection portion 514 and the fifteenth via hole connection portion 515.

For example, the eighth active pattern 38 and the ninth active pattern 39 are arranged at an interval in sequence along the second direction Y, which means that the eighth active pattern 38 and the ninth active pattern 39 are arranged in a column in the second direction Y. It should be noted that, considering process accuracy, there may be a certain misalignment between the fifth active pattern 35 and the sixth active pattern 36 in the first direction X.

By arranging the sixth bridge portion 66 between the eighth active portion 48 of the switching transistor T4 and the ninth active portion 49 of the second light-emitting control transistor T5, the resistance between the eighth active portion 48 and the ninth active portion 49 may be reduced, thereby improving the transmission efficiency of the electrical signal between the eighth active portion 48 and the ninth active portion 49, reducing the power consumption of the display substrate 100, and reducing a risk of electrostatic breakdown between the eighth active portion 48 and the ninth active portion 49.

In some embodiments, as shown in FIG. 7b, in the first active pattern 31, the second active pattern 32, the third active pattern 33, the fourth active pattern 34, the fifth active pattern 35, the sixth active pattern 36, the eighth active pattern 38, and the ninth active pattern 39, the area of the via hole connection portion in each active pattern is larger than the area of the active portion connected to the via hole connection portion. In this way, the size of the active portion may be reduced as much as possible, and thus the resistance of the active portion may be reduced, which may further improve the transmission efficiency of electrical signals in the pixel driving circuit P, reduce the power consumption of the display substrate 100, and reduce the electrostatic breakdown risk.

In some embodiments, as shown in FIG. 7b, the ends of each active pattern 3 (i.e., the end of the via hole connection portion) are chamfered or rounded. In this way, static electricity aggregation at the ends of the active pattern 3 may be reduced to avoid the electrostatic breakdown; and the distance between two adjacent active patterns 3 may also be increased to form an avoidance between adjacent active patterns 3, so as to further avoid the electrostatic breakdown.

In some embodiments, as shown in FIG. 7b, the seventh active pattern 37 corresponding to the driving transistor T3 further includes a sixteenth via hole connection portion 516 connected to the seventh active portion 47, and the sixteenth via hole connection portion 516 is located at an end of the seventh active portion 47 close to the ninth active portion 49. The sixteenth via hole connection portion 516 is also connected to the sixth bridge portion 66.

By connecting the sixteenth via hole connection portion 516 to the sixth bridge portion 66, the resistance between the eighth active portion 48 and the seventh active portion 47, and between the ninth active portion 49 and the seventh active portion 47 may be reduced, thereby improving the transmission efficiency of electrical signals between the eighth active portion 48 and the seventh active portion 47, and between the ninth active portion 49 and the seventh active portion 47, reducing the power consumption of the display substrate 100, and reducing a risk of electrostatic breakdown between the eighth active portion 48 and the seventh active portion 47, and between the ninth active portion 49 and the seventh active portion 47.

In some embodiments, as shown in FIG. 7b, along the first direction X, the eighth active pattern 38 and the fourth active pattern 34 corresponding to the compensation transistor T2 are arranged at an interval in sequence, the ninth active pattern 39 and the fifth active pattern 35 are arranged at an interval in sequence, and the seventh active pattern 37 is located between the eighth active pattern 38 and the fourth active pattern 34, and located between the ninth active pattern 39 and the fifth active pattern 35. Along the second direction Y, the seventh active pattern 37 is located between the fourth active pattern 34 and the fifth active pattern 35, and located between the eighth active pattern 38 and the ninth active pattern 39.

For example, the eighth active pattern 38 and the fourth active pattern 34 are arranged at an interval in sequence along the first direction X, which means that the eighth active pattern 38 and the fourth active pattern 34 are arranged in a row in the first direction X. It should be noted that, considering process accuracy, there may be a certain misalignment between the eighth active pattern 38 and the fourth active pattern 34 in the second direction Y.

For example, the ninth active pattern 39 and the fifth active pattern 35 are arranged at an interval in sequence along the first direction X, which means that the ninth active pattern 39 and the fifth active pattern 35 are arranged in a row in the first direction X. It should be noted that, considering process accuracy, there may be a certain misalignment between the ninth active pattern 39 and the fifth active pattern 35 in the second direction Y.

In some embodiments, as shown in FIG. 7a, the at least one gate conductive layer 7 includes a plurality of enable signal lines EM and a plurality of gate lines Ga extending along the first direction X and arranged at intervals in sequence along the second direction Y, and the enable signal lines EM and the gate lines Ga are arranged alternately. An enable signal line EM covers the fifth active portions 45 corresponding to the first light-emitting control transistors T6 in the pixel driving circuits P₁ in the i-th row, and the ninth active portions 49 corresponding to the second light-emitting control transistors T5 in the pixel driving circuits P₁ in the i-th row. A gate line Ga covers the third active portions 43 and the fourth active portions 44 corresponding to the compensation transistors T2 in the pixel driving circuits P₁ in the i-th row, and the eighth active portions 48 corresponding to the switching transistors T4 in the pixel driving circuits P₁ in the i-th row. Here, N is a positive integer.

For example, the pixel driving circuits P located in the same row share the enable signal line EM and the gate line Ga. In this way, the space of the display substrate 100 occupied by the enable signal lines EM and the gate lines Ga may be reduced, and the manufacturing process of the display substrate 100 may be simplified.

By covering the fifth active portion 45 corresponding to the first light-emitting control transistor T6 with one enable signal line EM, a portion, covered by the enable signal line EM, of the fifth active portion 45 may form the gate of the first light-emitting control transistor T6. When an enable signal is input to the enable signal line EM, the on-off state of the first light-emitting control transistor T6 may be controlled.

By covering the ninth active portion 49 corresponding to the second light-emitting control transistor T5 with one enable signal line EM, a portion, covered by the enable signal line EM, of the ninth active portion 49 may form the gate of the second light-emitting control transistor T5. When an enable signal is input to the enable signal line EM, the on-off state of the second light-emitting control transistor T5 may be controlled.

By covering the third active portion 43 and the fourth active portion 44 corresponding to the compensation transistor T2 with one gate line Ga, portions, covered by the gate line Ga, of the third active portion 43 and the fourth active portion 44 may form the gate of the compensation transistor T2. When a gate line signal is input to the gate line Ga, the on-off state of the compensation transistor T2 may be controlled.

By covering the eighth active portion 48 corresponding to the switching transistor T4 with one gate line Ga, a portion, covered by the gate line Ga, of the eighth active portion 48 may form the gate electrode of the switching transistor T4. When a gate line signal is input to the gate line Ga, the on-off state of the switching transistor T4 may be controlled.

In some embodiments, as shown in FIG. 7c, the enable signal lines EM and the gate lines Ga are all located in the first gate conductive layer 71.

By arranging the enable signal lines EM and the gate lines Ga in the first gate conductive layer 71 close to the side of the semiconductor layer 2, it is beneficial for signals transmitted on the enable signal lines EM and the gate lines Ga to control active portions 4 of the transistors T in the semiconductor layer 2.

In some embodiments, the storage capacitor Cst in the pixel driving circuit P overlaps the seventh active pattern 37 of the driving transistor T3. The storage capacitor Cst includes a first electrode plate 713 and a second electrode plate 721. As shown in FIG. 7c, the first electrode plate 713 is located in the first gate conductive layer 71; as shown in FIG. 7e, the second electrode plate 721 is located in the second gate conductive layer 72. As shown in FIG. 7a, the second electrode plates 721 of the storage capacitors Cst in pixel driving circuits P₁ in the i-th row are connected and form a one-piece structure.

For example, the storage capacitor Cst overlaps the seventh active pattern 37, which means that an orthographic projection of the storage capacitor Cst on the substrate 1 overlaps an orthographic projection of the seventh active pattern 37 on the substrate 1.

By overlapping the storage capacitor Cst with the seventh active pattern 37, the first electrode plate 713 of the storage capacitor Cst located in the first gate conductive layer 71 may control the seventh active portion 47 in the seventh active pattern 37, thereby controlling the on-off state of the driving transistor T3.

By arranging the second electrode plates 721 of the storage capacitors Cst in the same row as a connected one-piece structure, the stability of the voltages of the second electrode plates 721 may be maintained, and the stability of the amount of charge stored in the storage capacitor Cst may be maintained.

In some embodiments, as shown in FIG. 7e, the second gate conductive layer 72 further includes a plurality of shielding patterns 722 configured to receive constant voltage electrical signals. As shown in FIGS. 7a and 7e, the shielding pattern 722 overlaps the second bridge portion 62 and/or the third bridge portion 63 corresponding to the compensation transistor T2.

By allowing the shielding pattern 722 to receive the constant voltage electrical signal, the shielding pattern 722 may shield an electromagnetic signal in the thickness direction of the display substrate 100.

For example, the constant voltage electrical signal received by the shielding pattern 722 may be the power supply voltage signal transmitted on the power supply voltage signal line VDD.

For example, the shielding pattern 722 overlaps the second bridge portion 62 and/or the third bridge portion 63 corresponding to the compensation transistor T2, which means that an orthographic projection of the shielding pattern 722 on the substrate 1 overlaps an orthographic projection of the second bridge portion 62 and/or an orthographic projection of the third bridge portion 63 on the substrate 1.

By overlapping the shielding pattern 722 with the second bridge portion 62 and/or the third bridge portion 63, the shielding pattern 722 may provide shielding protection for the second bridge portion 62 and/or the third bridge portion 63, and may maintain the stability of the electrical signal transmitted on the second bridge portion 62 and/or the electrical signal transmitted on the third bridge portion 63.

In some embodiments, as shown in FIG. 7b, the eighth active pattern 38 further includes a seventeenth via hole connection portion 517 connected to the eighth active portion 48, and the seventeenth via hole connection portion 517 is located at an end of the eighth active portion 48 away from the fourteenth via hole connection portion 514. The ninth active pattern 39 further includes an eighteenth via hole connection portion 518 connected to the ninth active portion 49, and the eighteenth via hole connection portion 518 is located at an end of the ninth active portion 49 away from the fifteenth via hole connection portion 515.

In some examples, the number of source-drain electrode layers 8 is two. The two source-drain electrode layers 8 are the first source-drain electrode layer 81 and the second source-drain electrode layer 82 located on a side of the first source-drain electrode layer 81 away from the semiconductor layer 2. As shown in FIG. 7a, the first source-drain electrode layer 81 includes a plurality of power supply voltage signal lines VDD extending along the second direction Y and arranged at intervals in sequence along the first direction X. As shown in FIG. 7a, the second source-drain electrode layer 82 includes a plurality of data lines Da extending along the second direction Y and arranged at intervals in sequence along the first direction X. As shown in FIG. 7a, the power supply voltage signal lines VDD and the data lines Da are arranged alternately.

In some examples, a power supply voltage signal line VDD overlaps the pixel driving circuits P₁ in the j-th column. The power supply voltage signal line VDD is electrically connected to the eighteenth via hole connection portions 518 of the ninth active patterns 39 corresponding to the second light-emitting control transistors T5 in the pixel driving circuits P₁ in the j-th column. A data line Da is located between two adjacent columns of pixel driving circuits P. The data line Da is electrically connected to the seventeenth via hole connection portions 517 of the eighth active patterns 38 corresponding to the switching transistors T4 in the pixel driving circuits P₁ in the j-th column. Here, j is a positive integer.

For example, there are various ways for the power supply voltage signal line VDD to be electrically connected to the eighteenth via hole connection portion 518.

For example, as shown in FIGS. 7a and 7c, the first gate conductive layer 71 further includes a third connection pattern 714, and an orthographic projection of the third connection pattern 714 on the substrate 1 overlaps an orthographic projection of the power supply voltage signal line VDD on the substrate 1 and an orthographic projection of the eighteenth via hole connection portion 518 on the substrate 1. The power supply voltage signal line VDD is electrically connected to the third connection pattern 714 through a via hole, and the third connection pattern 714 is also electrically connected to the eighteenth via hole connection portion 518 through a via hole. Thus, the electrical connection between the power supply voltage signal line VDD and the eighteenth via hole connection portion 518 is achieved.

By electrically connecting the power supply voltage signal line VDD to the eighteenth via hole connection portion 518 of the ninth active pattern 39 corresponding to the second light-emitting control transistors T5, the power supply voltage signal on the power supply voltage signal line VDD may be transmitted to the second light-emitting control transistors T5.

For example, as shown in FIG. 7f, the first source-drain electrode layer 81 further includes a fourth connection pattern 811, a fifth connection pattern 812, and a sixth connection pattern 813. The fourth connection pattern 811, the fifth connection pattern 812, and the sixth connection pattern 813 all extend along the second direction Y.

For example, there is an overlapping region between an orthographic projection of the fourth connection pattern 811 on the substrate 1 and an orthographic projection of the first active pattern 31 of the first reset transistor T1 on the substrate 1, and the first reset transistor T1 is connected to the first initial signal line Vinit1 through the fourth connection pattern 811.

For example, as shown in FIGS. 7a to 7d and 7f, one end of the fourth connection pattern 811 is connected to the first initial signal line Vinit1 through a via hole, the other end of the fourth connection pattern 811 is connected to the first connection pattern 711 located in the first gate conductive layer 71 through a via hole, and the first connection pattern 711 is connected to the twelfth via hole connection portion 512 of the first active pattern 31 in the first reset transistor T1 through a via hole, thereby achieving the electrical connection between the first reset transistor T1 and the first initial signal line Vinit1.

For example, as shown in FIGS. 7a to 7d and 7f, the fifth connection pattern 812 is located between the fourth active pattern 34 and the eighth active pattern 38 in the first direction X, and the fifth connection pattern 812 is located between the first active pattern 31 and the seventh active pattern 37 in the second direction Y. The first electrode plate 713 of the storage capacitor Cst is electrically connected to the sixth via hole connection portion 56 of the third active pattern 33 in the compensation transistor T2 through the fifth connection pattern 812.

For example, as shown in FIGS. 7a, 7b and 7f, one end of the fifth connection pattern 812 is connected to the first electrode plate 713 of the storage capacitor Cst through a via hole, and the other end of the fifth connection pattern 812 is connected to the sixth via hole connection portion 56 of the third active pattern 33 in the compensation transistor T2 through a via hole, thereby achieving the electrical connection between the first electrode plate 713 of the storage capacitor Cst and the sixth via hole connection portion 56.

For example, as shown in FIGS. 7a to 7d and 7f, an orthographic projection of the sixth connection pattern 813 on the substrate 1 overlaps an orthographic projection of the sixth active pattern 36 of the second reset transistor T7 on the substrate 1. The second reset transistor T7 is connected to the second initial signal line Vinit2 through the sixth connection pattern 813.

For example, as shown in FIGS. 7a to 7d and 7f, one end of the sixth connection pattern 813 is connected to the second initial signal line Vinit2 through a via hole, the other end of the sixth connection pattern 813 is connected to the second connection pattern 712 through a via hole, and the second connection pattern 712 is electrically connected to the eleventh via hole connection portion 511 of the second reset transistor T7, thereby achieving the electrical connection between the second reset transistor T7 and the second initial signal line Vinit2.

It should be noted that there are various ways for the data line Da to be electrically connected to the seventeenth via hole connection portion 517 of the eighth active pattern 38 corresponding to the switching transistor T4. For example, as shown in FIGS. 7a and 7f, the first source-drain electrode layer 81 further includes a seventh connection pattern 814, the data line Da is connected to the seventh connection pattern 814 through a via hole, and the seventh connection pattern 814 is electrically connected to the seventeenth via hole connection portion 517 through a via hole.

By electrically connecting the data line Da to the seventeenth via hole connection portion 517 of the eighth active pattern 38 corresponding to the switching transistor T4, the data signal on the data line Da may be transmitted to the switching transistor T4.

In the above embodiments, the bridge portions 6 are all located in the first gate conductive layer 71 in FIG. 7a for illustration. It should be noted that, in a pixel driving circuit P, the number and arrangement of the bridge portions 6 may be set arbitrarily, and the present disclosure is not limited thereto. Some embodiments are listed below to illustrate the number and arrangement of the bridge portions 6.

### First Possible Embodiment

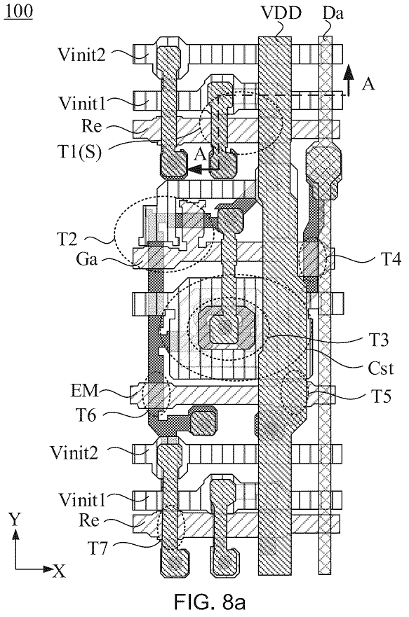

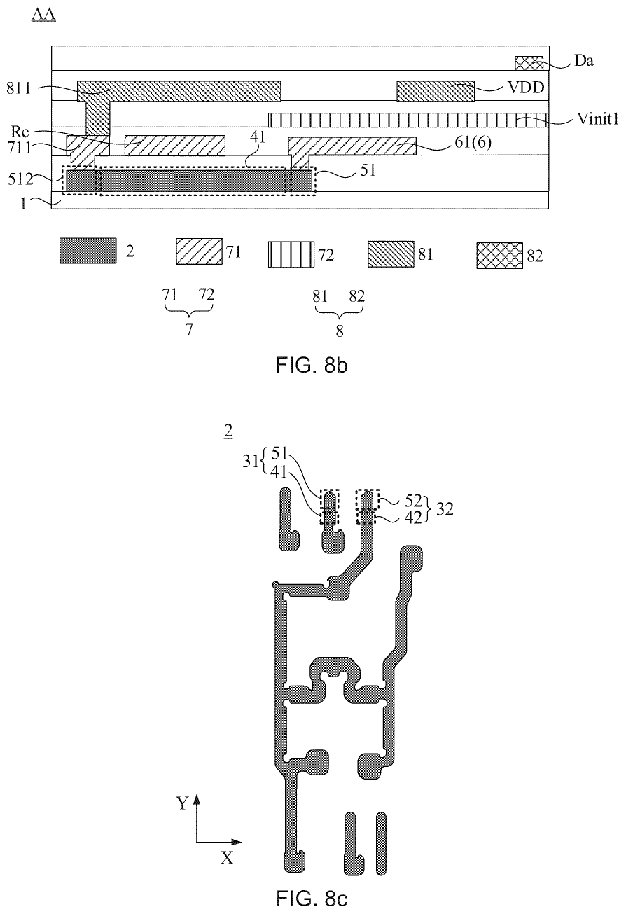

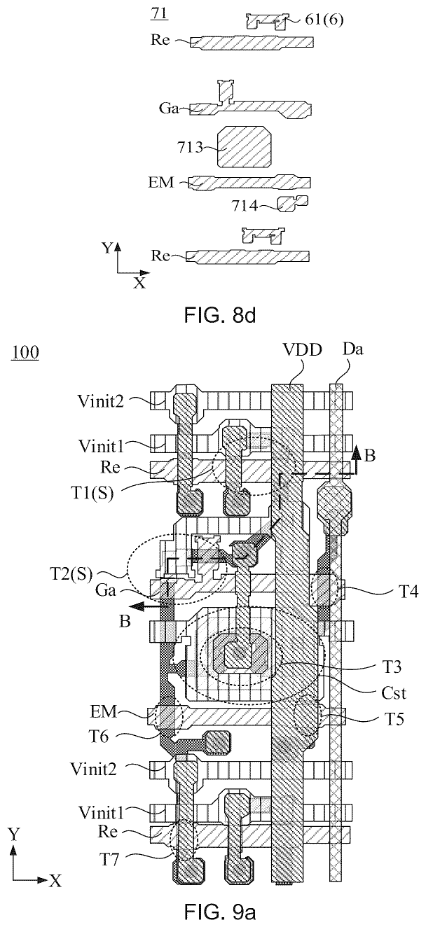

As shown in FIG. 8a, FIG. 8a is a structural diagram of the display substrate 100 in this embodiment. As shown in FIG. 8b, FIG. 8b is a sectional view of the display substrate 100 shown in FIG. 8a taken along the direction AA. As shown in FIG. 8c, FIG. 8c is a structural diagram of the semiconductor layer 2 in the display substrate 100 shown in FIG. 8a. Compared with the structure of the semiconductor layer 2′ in FIG. 5 in one implementation, the first via hole connection portion 51 and the second via hole connection portion 52 of the semiconductor layer 2 in FIG. 8c are in a disconnected state.

FIG. 8d is a structural diagram of the first gate conductive layer 71 in the display substrate shown in FIG. 8a. The plurality of bridge portions 6 in the display substrate 100 include the first bridge portion 61 located in the first gate conductive layer 71, and the first bridge portion 61 is connected to the first via hole connection portion 51 of the first active pattern 31 and the second via hole connection portion 52 of the second active pattern 32. The first gate conductive layer 71 further includes: the reset signal line Re, the gate line Ga, the first electrode plate 713, the enable signal line EM, and the third connection pattern 714 arranged at intervals in sequence along the second direction Y.

With the arrangement of the first bridge portion 61, the first active pattern 31 and the second active pattern 32 may be connected through the first bridge portion 61, thereby reducing the connection resistance between the first active pattern 31 and the second active pattern 32, improving the transmission efficiency of the electrical signal between the first active pattern 31 and the second active pattern 32, reducing the power consumption of the display substrate 100, and reducing the risk of electrostatic breakdown.

In this embodiment, the structure and arrangement of the second gate conductive layer 72 are the same as those of the second gate conductive layer in FIG. 7e, the structure and arrangement of the first source-drain electrode layer 81 are the same as those of the first source-drain electrode layer in FIG. 7f, and the structure and arrangement of the second source-drain electrode layer 82 are the same as those of the second source-drain electrode layer in FIG. 7g, which will not be repeated here.

### Second Possible Embodiment

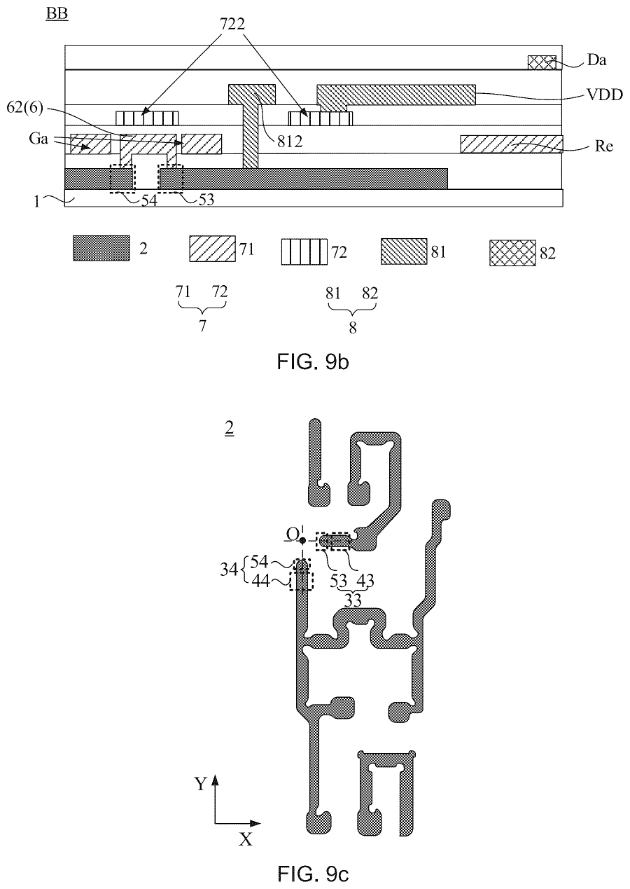

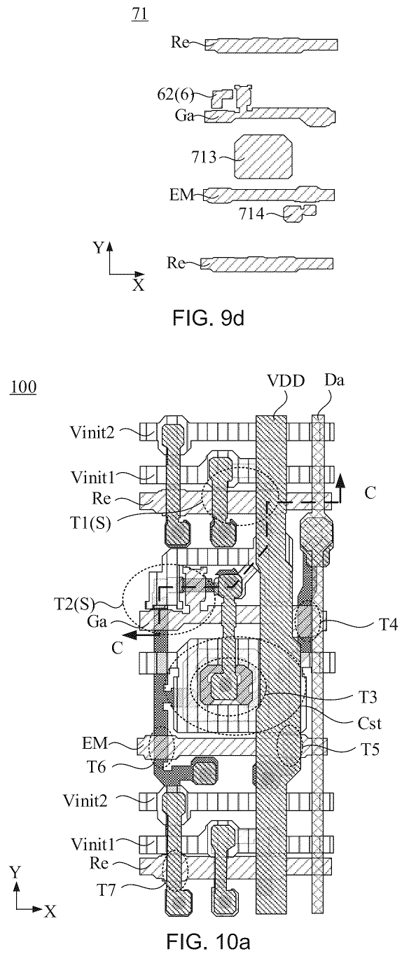

As shown in FIG. 9a, FIG. 9a is a structural diagram of a display substrate 100 in this embodiment. As shown in FIG. 9b, FIG. 9b is a sectional view of the display substrate 100 shown in FIG. 9a taken along the direction BB. As shown in FIG. 9c, FIG. 9c is a structural diagram of the semiconductor layer 2 in the display substrate 100 shown in FIG. 9a. Compared with the structure of the semiconductor layer 2′ in FIG. 5 in one implementation, the third via hole connection portion 53 and the fourth via hole connection portion 54 of the semiconductor layer 2 in FIG. 9c are in a disconnected state.

As shown in FIG. 9d, FIG. 9d is a structural diagram of the first gate conductive layer 71 in the display substrate 100 shown in FIG. 9a. The plurality of bridge portions 6 in the display substrate 100 include the second bridge portion 62 located in the first gate conductive layer 71, and the second bridge portion 62 is connected to the third via hole connection portion 53 of the third active pattern 33 and the fourth via hole connection portion 54 of the fourth active pattern 34. The first gate conductive layer 71 further includes: the reset signal line Re, the gate line Ga, the first electrode plate 713, the enable signal line EM, and the third connection pattern 714 arranged at intervals in sequence along the second direction Y.

With the arrangement of the second bridge portion 62, the third active pattern 33 and the fourth active pattern 34 may be connected through the second bridge portion 62, thereby reducing the connection resistance between the third active pattern 33 and the fourth active pattern 34, improving the transmission efficiency of the electrical signal between the third active pattern 33 and the fourth active pattern 34, reducing the power consumption of the display substrate 100, and reducing the risk of electrostatic breakdown.

In this embodiment, the structure and arrangement of the second gate conductive layer 72 are the same as those of the second gate conductive layer in FIG. 7e, the structure and arrangement of the first source-drain electrode layer 81 are the same as those of the first source-drain electrode layer in FIG. 7f, and the structure and arrangement of the second source-drain electrode layer 82 are the same as those of the second source-drain electrode layer in FIG. 7g, which will not be repeated here.

### Third Possible Embodiment

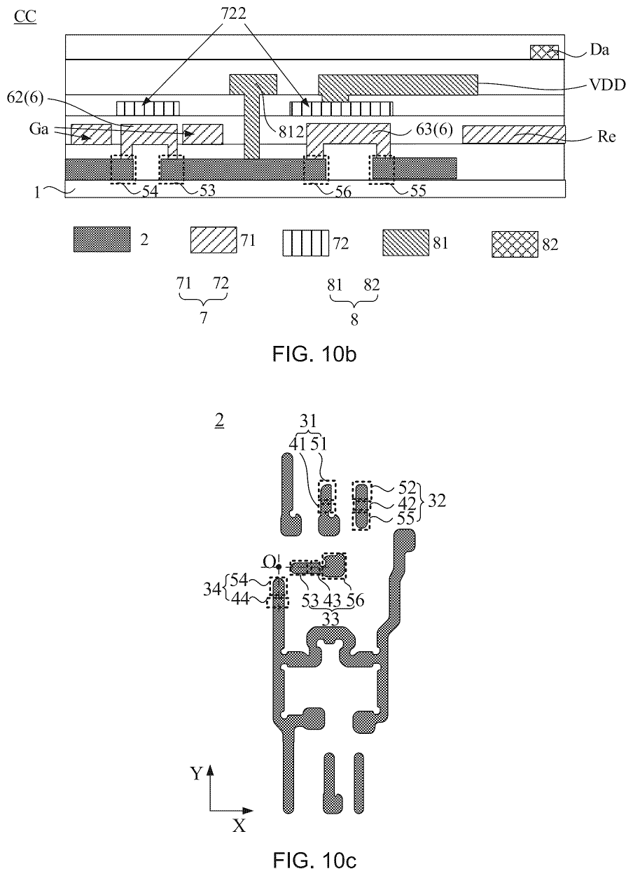

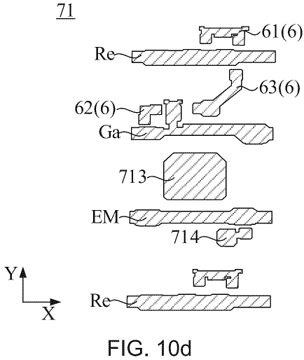

As shown in FIG. 10a, FIG. 10a is a structural diagram of a display substrate 100 in this embodiment. As shown in FIG. 10b, FIG. 10b is a sectional view of the display substrate 100 shown in FIG. 10a taken along the direction CC. As shown in FIG. 10c, FIG. 10c is a structural diagram of the semiconductor layer 2 in the display substrate 100 shown in FIG. 10a. Compared with the structure of the semiconductor layer 2′ in FIG. 5 in one implementation, in the semiconductor layer 2 in FIG. 10c, the first via hole connection portion 51 and the second via hole connection portion 52 are in a disconnected state, the fifth via hole connection portion 55 and the sixth via hole connection portion 56 are in a disconnected state, and the third via hole connection portion 53 and the fourth via hole connection portion 54 are in a disconnected state.

As shown in FIG. 10d, FIG. 10d is a structural diagram of the first gate conductive layer 71 in the display substrate 100 shown in FIG. 10a. The plurality of bridge portions 6 in the display substrate 100 include the first bridge portion 61, the second bridge portion 62 and the third bridge portion 63 located in the first gate conductive layer 71. The first bridge portion 61 is connected to the first via hole connection portion 51 of the first active pattern 31 and the second via hole connection portion 52 of the second active pattern 32. The second bridge portion 62 is connected to the third via hole connection portion 53 of the third active pattern 33 and the fourth via hole connection portion 54 of the fourth active pattern 34. The third bridge portion 63 is connected to the fifth via hole connection portion 55 and the sixth via hole connection portion 56. The first gate conductive layer 71 further includes: the reset signal line Re, the gate line Ga, the first electrode plate 713, the enable signal line EM, and the third connection pattern 714 arranged at intervals in sequence along the second direction Y.

With the arrangement of the first bridge portion 61, the second bridge portion 62, and the third bridge portion 63 in the display substrate 100, the first active pattern 31 and the second active pattern 32 may be connected through the first bridge portion 61, the second active pattern 32 and the third active pattern 33 may be connected through the third bridge portion 63, and the third active pattern 33 and the fourth active pattern 34 may be connected through the second bridge portion 62, thereby simultaneously reducing the connection resistance between the first active pattern 32 and the second active pattern 32, the connection resistance between the second active pattern 32 and the third active pattern 33, and the connection resistance between the third active pattern 33 and the fourth active pattern 34, improving the transmission efficiency of the electrical signal between the above active patterns 3, reducing the power consumption of the display substrate 100, and reducing the risk of electrostatic breakdown.

In this embodiment, the structure and arrangement of the second gate conductive layer 72 are the same as those of the second gate conductive layer in FIG. 7e, the structure and arrangement of the first source-drain electrode layer 81 are the same as those of the first source-drain electrode layer in FIG. 7f, and the structure and arrangement of the second source-drain electrode layer 82 are the same as those of the second source-drain electrode layer in FIG. 7g, which will not be repeated here.

### Fourth Possible Embodiment

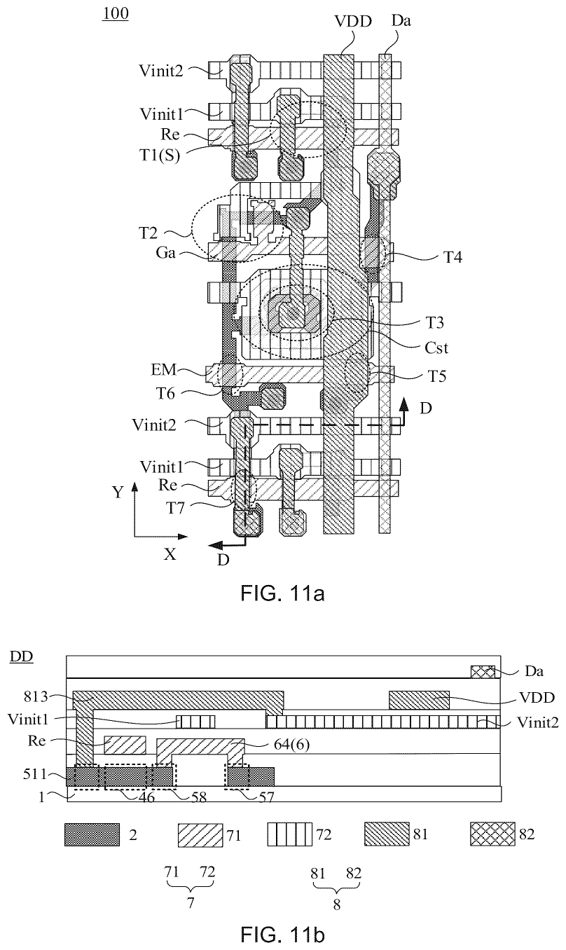

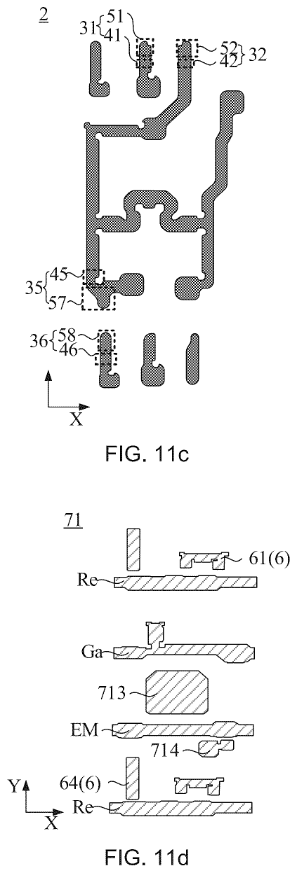

As shown in FIG. 11a, FIG. 11a is a structural diagram of a display substrate 100 in this embodiment. As shown in FIG. 11b, FIG. 11b is a sectional view of the display substrate 100 shown in FIG. 11a taken along the direction DD. As shown in FIG. 11c, FIG. 11c is a structural diagram of the semiconductor layer 2 in the display substrate 100 shown in FIG. 11a. Compared with the structure of the semiconductor layer 2′ in FIG. 5 in one implementation, in the semiconductor layer 2 in FIG. 11c, the first via hole connection portion 51 and the second via hole connection portion 52 are in a disconnected state, and the seventh via hole connection portion 57 and the eighth via hole connection portion 58 are in a disconnected state.

As shown in FIG. 11d, FIG. 11d is a structural diagram of the first gate conductive layer 71 in the display substrate 100 shown in FIG. 11a. The plurality of bridge portions 6 in the display substrate 100 include the first bridge portion 61 and the fourth bridge portion 64 located in the first gate conductive layer 71. The first bridge portion 61 is connected to the first via hole connection portion 51 of the first active pattern 31 and the second via hole connection portion 52 of the second active pattern 32, and the fourth bridge portion 64 is connected to the seventh via hole connection portion 57 of the fifth active pattern 35 and the eighth via hole connection portion 58 of the sixth active pattern 36. The first gate conductive layer 71 further includes: the reset signal line Re, the gate line Ga, the first electrode plate 713, the enable signal line EM, and the third connection pattern 714 arranged at intervals in sequence along the second direction Y.

With the arrangement of the first bridge portion 61 and the fourth bridge portion 64 in the display substrate 100, the first active pattern 31 and the second active pattern 32 may be connected through the first bridge portion 61, and the fifth active pattern 35 and the sixth active pattern 36 may be connected through the fourth bridge portion 64, thereby simultaneously reducing the connection resistance between the first active pattern 31 and the second active pattern 32, and the connection resistance between the fifth active pattern 35 and the sixth active pattern 36, improving the transmission efficiency of the electrical signal between the above active patterns 3, reducing the power consumption of the display substrate 100, and reducing the risk of electrostatic breakdown.

In this embodiment, the structure and arrangement of the second gate conductive layer 72 are the same as those of the second gate conductive layer in FIG. 7e, the structure and arrangement of the first source-drain electrode layer 81 are the same as those of the first source-drain electrode layer in FIG. 7f, and the structure and arrangement of the second source-drain electrode layer 82 are the same as those of the second source-drain electrode layer in FIG. 7g, which will not be repeated here.

### Fifth Possible Embodiment

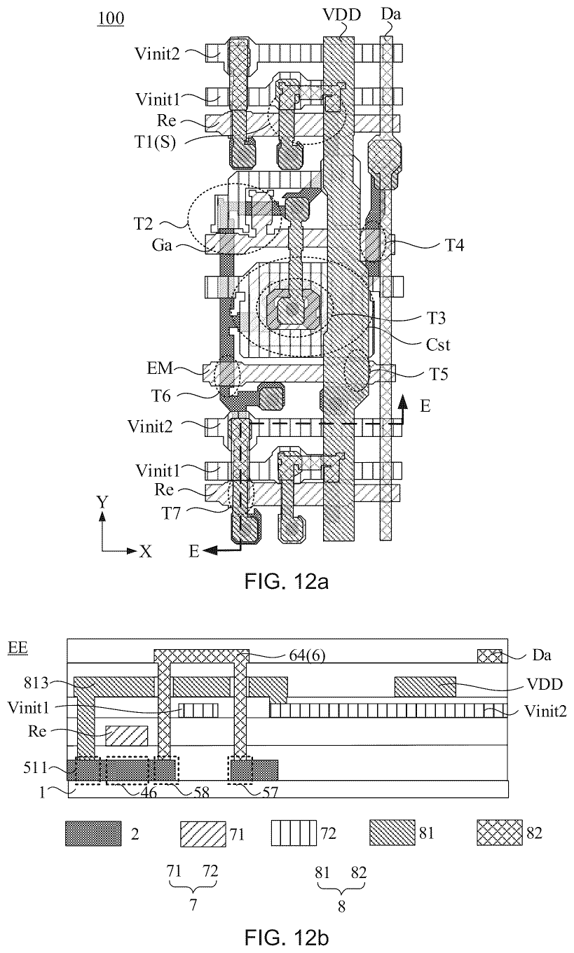

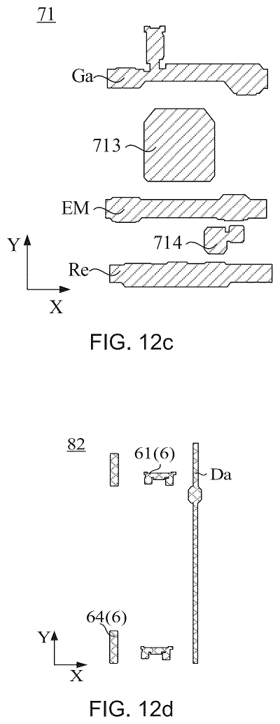

As shown in FIG. 12a, FIG. 12a is a structural diagram of a display substrate 100 in this embodiment. As shown in FIG. 12b, FIG. 12b is a sectional view of the display substrate 100 shown in FIG. 12a taken along the direction EE.

As shown in FIG. 12c, FIG. 12c is a structural diagram of the first gate conductive layer 71 in the display substrate 100 shown in FIG. 12a. The first gate conductive layer 71 includes: the reset signal line Re, the gate line Ga, the first electrode plate 713, the enable signal line EM, and the third connection pattern 714 arranged at intervals along the second direction Y.

As shown in FIG. 12d, FIG. 12d is a structural diagram of the second source-drain electrode layer 82 in the display substrate 100 shown in FIG. 12a. The plurality of bridge portions 6 in the display substrate 100 include the first bridge portion 61 and the fourth bridge portion 64 located in the second source-drain electrode layer 82. The first bridge portion 61 is connected to the first via hole connection portion 51 of the first active pattern 31 and the second via hole connection portion 52 of the second active pattern 32, and the fourth bridge portion 64 is connected to the seventh via hole connection portion 57 of the fifth active pattern 35 and the eighth via hole connection portion 58 of the sixth active pattern 36. The second source-drain electrode layer 82 further includes the plurality of data lines Da extending along the second direction Y and arranged at intervals in sequence along the first direction X.

It should be noted that, as shown in FIG. 12b, in the case where the fourth bridge portion 64 of the second source-drain electrode layer 82 is connected to the seventh via hole connection portion 57 and the eighth via hole connection portion 58, in order to avoid the via holes of the fourth bridge portion 64 interfere with the sixth connection pattern 813 of the first source-drain electrode layer 81, it may be that no conductive material is provided at the positions of the sixth connection pattern 813 corresponding to the seventh via hole connection portion 57 and the eighth via hole connection portion 58 (that is, the conductive material of the sixth connection pattern 813 surrounds the positions of the seventh via hole connection portion 57 and the eighth via hole connection portion 58), or the sixth connection pattern 813 bypasses the positions of the seventh via hole connection portion 57 and the eighth via hole connection portion 58.

With the arrangement of the first bridge portion 61 and the fourth bridge portion 64 in the display substrate 100, the first active pattern 31 and the second active pattern 32 may be connected through the first bridge portion 61, and the fifth active pattern 35 and the sixth active pattern 36 may be connected through the fourth bridge portion 64, thereby simultaneously reducing the connection resistance between the first active pattern 32 and the second active pattern 32, and the connection resistance between the fifth active pattern 35 and the sixth active pattern 36, improving the transmission efficiency of the electrical signal between the above active patterns 3, reducing the power consumption of the display substrate 100, and reducing the risk of electrostatic breakdown.

It can be understood that, in the one implementation described above, after the semiconductor layer 2′ is doped and before the second source-drain electrode layer is formed, a hole-formation process is required to form via holes reaching the semiconductor layer 2′ at positions where the via holes need to be formed (e.g., positions corresponding to first electrodes or second electrodes of some transistors), and then the material of the second source-drain electrode layer is filled into the via holes to lead out the first electrodes or second electrodes of the transistors.

In this embodiment, by arranging the bridge portions 6 in the second source-drain electrode layer 82, the via holes reaching the via hole connection portions 5 may be simultaneously formed in the hole-formation process. In this way, compared with the one implementation described above, this embodiment does not require an additional hole-formation process and a mask, which may avoid increasing the manufacturing process of the display substrate 100 and increasing the manufacturing cost of the display substrate 100.

In this embodiment, the structure of the semiconductor layer 2 is the same as that of the semiconductor layer 2 in FIG. 11c, the structure and arrangement of the second gate conductive layer 72 are the same as those of the second gate conductive layer in FIG. 7e, and the structure and arrangement of the first source-drain electrode layer 81 are the same as those of the first source-drain electrode layer in FIG. 7f, which will not be repeated here.

### Sixth Possible Embodiment

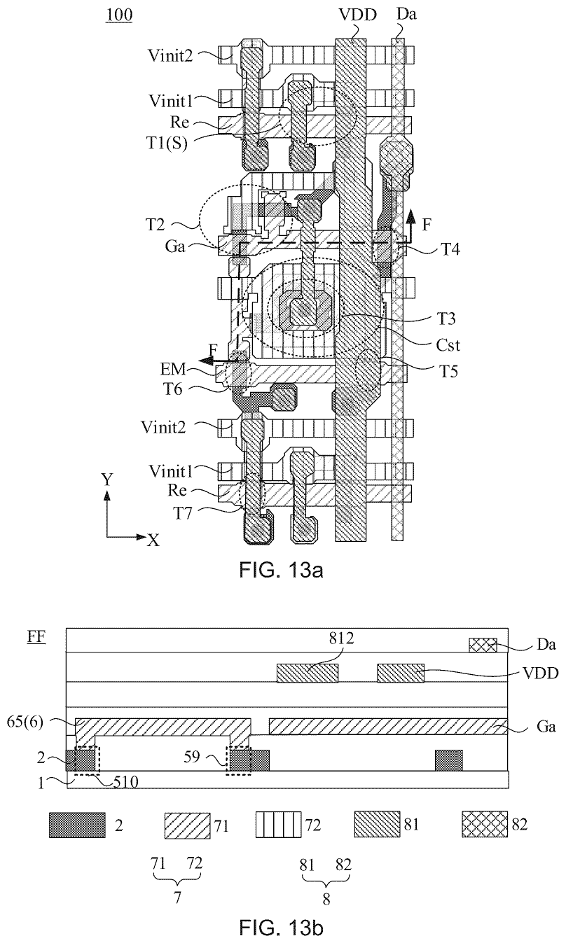

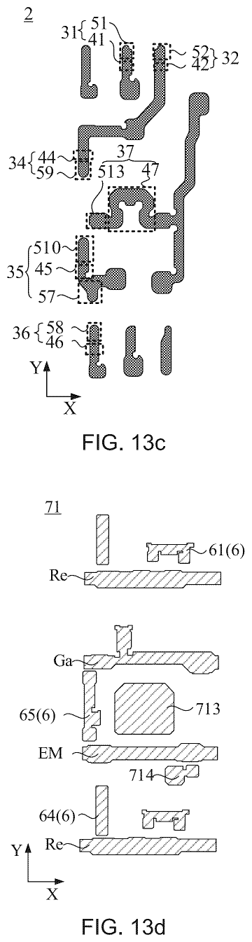

As shown in FIG. 13a, FIG. 13a is a structural diagram of a display substrate 100 in this embodiment. As shown in FIG. 13b, FIG. 13b is a sectional view of the display substrate 100 shown in FIG. 13a taken along the direction FF. As shown in FIG. 13c, FIG. 13c is a structural diagram of the semiconductor layer 2 in the display substrate 100 shown in FIG. 13a. Compared with the structure of the semiconductor layer 2′ in FIG. 5 in one implementation, in the semiconductor layer 2 in FIG. 13c, the first via hole connection portion 51 and the second via hole connection portion 52 are in a disconnected state, the seventh via hole connection portion 57 and the eighth via hole connection portion 58 are in a disconnected state, and the ninth via hole connection portion 59 and the tenth via hole connection portion 510 are in a disconnected state.

As shown in FIG. 13d, FIG. 13d is a structural diagram of the first gate conductive layer 71 in the display substrate 100 shown in FIG. 13a. The plurality of bridge portions 6 in the display substrate 100 include the first bridge portion 61, the fourth bridge portion 64 and the fifth bridge portion 65 located in the first gate conductive layer 71. The first bridge portion 61 is connected to the first via hole connection portion 51 of the first active pattern 31 and the second via hole connection portion 52 of the second active pattern 32, the fourth bridge portion 64 is connected to the seventh via hole connection portion 57 of the fifth active pattern 35 and the eighth via hole connection portion 58 of the sixth active pattern 36, and the fifth bridge portion 65 is connected to the ninth via hole connection portion 59 of the fourth active pattern 34 and the tenth via hole connection portion 510 of the fifth active pattern 35. The first gate conductive layer 71 further includes: the reset signal line Re, the gate line Ga, the first electrode plate 713, the enable signal line EM, and the third connection pattern 714 arranged at intervals in sequence along the second direction Y.

With the arrangement of the first bridge portion 61, the fourth bridge portion 64, and the fifth bridge portion 65 in the display substrate 100, the first active pattern 31 and the second active pattern 32 may be connected through the first bridge portion 61, the fifth active pattern 35 and the sixth active pattern 36 may be connected through the fourth bridge portion 64, and the fourth active pattern 34 and the fifth active pattern 35 may be connected through the fifth bridge portion 65, thereby simultaneously reducing the connection resistance between the first active pattern 31 and the second active pattern 32, the connection resistance between the fifth active pattern 35 and the sixth active pattern 36, and the connection resistance between the fourth active pattern 34 and the fifth active pattern 35, improving the transmission efficiency of the electrical signal between the above active patterns 3, reducing the power consumption of the display substrate 100, and reducing the risk of electrostatic breakdown.

In this embodiment, the structure and arrangement of the second gate conductive layer 72 are the same as those of the second gate conductive layer in FIG. 7e, the structure and arrangement of the first source-drain electrode layer 81 are the same as those of the first source-drain electrode layer in FIG. 7f, and the structure and arrangement of the second source-drain electrode layer 82 are the same as those of the second source-drain electrode layer in FIG. 7g, which will not be repeated here.

Furthermore, the fifth bridge portion 65 is also connected to the thirteenth via hole connection portion 513 of the seventh active pattern 37, so that the fourth active pattern 34, the fifth active pattern 35 and the seventh active pattern 37 may be connected through the fifth bridge portion 65, thereby reducing the connection resistance between the fourth active pattern 34, the fifth active pattern 35 and the seventh active pattern 37, improving the transmission efficiency of the electrical signal between the above active patterns 3, reducing the power consumption of the display substrate 100, and reducing the risk of electrostatic breakdown.

### Seventh Possible Embodiment

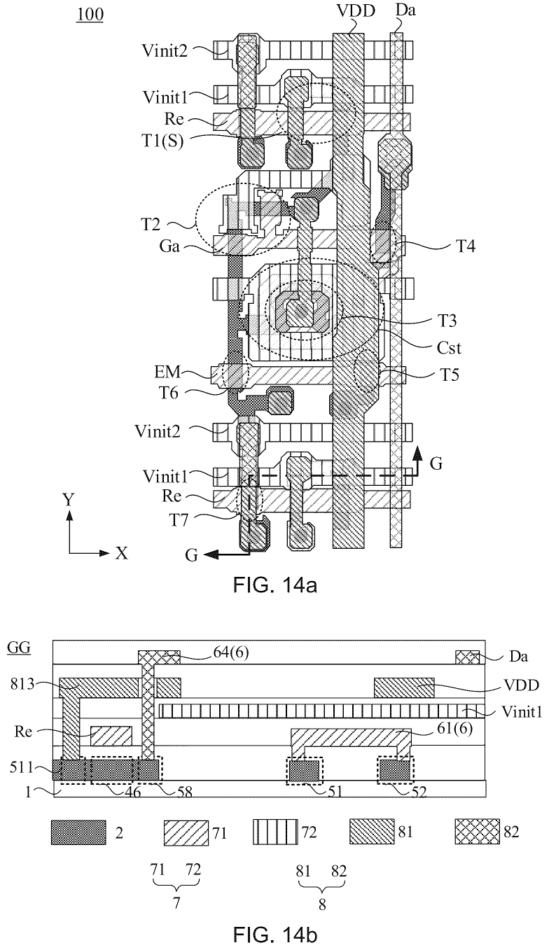

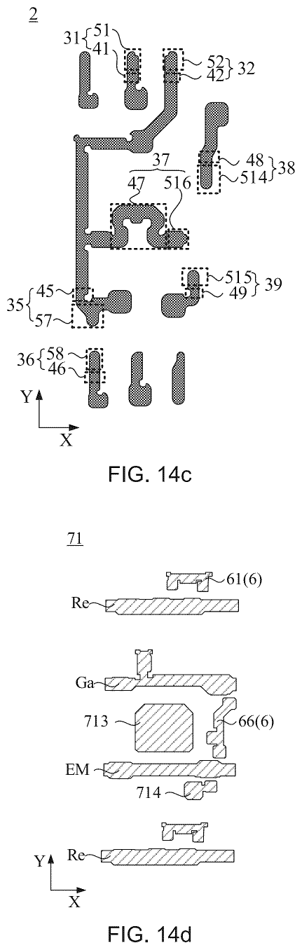

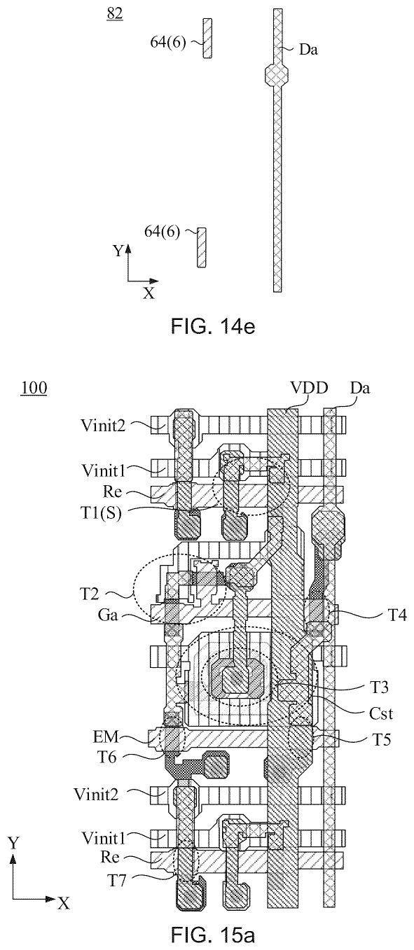

As shown in FIG. 14a, FIG. 14a is a structural diagram of a display substrate 100 in this embodiment. As shown in FIG. 14b, FIG. 14b is a sectional view of the display substrate 100 shown in FIG. 14a taken along the direction GG. As shown in FIG. 14c, FIG. 14c is a structural diagram of the semiconductor layer 2 in the display substrate 100 shown in FIG. 14a. Compared with the structure of the semiconductor layer 2′ in FIG. 5 in one implementation, in the semiconductor layer 2 in FIG. 14c, the first via hole connection portion 51 and the second via hole connection portion 52 are in a disconnected state, the seventh via hole connection portion 57 and the eighth via hole connection portion 58 are in a disconnected state, and the fourteenth via hole connection portion 514 and the fifteenth via hole connection portion 515 are in a disconnected state.

As shown in FIG. 14d, FIG. 14d is a structural diagram of the first gate conductive layer 71 in the display substrate 100 shown in FIG. 14a. The plurality of bridge portions 6 in the display substrate 100 include the first bridge portion 61 and the sixth bridge portion 66 located in the first gate conductive layer 71. The first bridge portion 61 is connected to the first via hole connection portion 51 of the first active pattern 31 and the second via hole connection portion 52 of the second active pattern 32, and the sixth bridge portion 66 is connected to the fourteenth via hole connection portion 514 of the eighth active pattern 38 and the fifteenth via hole connection portion 515 of the ninth active pattern 39. The first gate conductive layer 71 further includes: the reset signal line Re, the gate line Ga, the first electrode plate 713, the enable signal line EM, and the third connection pattern 714 arranged at intervals in sequence along the second direction Y.

As shown in FIG. 14e, FIG. 14e is a structural diagram of the second source-drain electrode layer 82 in the display substrate 100 shown in FIG. 14a. The plurality of bridge portions 6 in the display substrate 100 further include the fourth bridge portion 64 located in the second source-drain electrode layer 82, and the fourth bridge portion 64 is connected to the seventh via hole connection portion 57 of the fifth active pattern 35 and the eighth via hole connection portion 58 of the sixth active pattern 36. The second source-drain electrode layer 82 further includes the plurality of data lines Da extending along the second direction Y and arranged at intervals in sequence along the first direction X.

With the arrangement of the first bridge portion 61, the fourth bridge portion 64, and the sixth bridge portion 66 in the display substrate 100, the first active pattern 31 and the second active pattern 32 may be connected through the first bridge portion 61, the fifth active pattern 35 and the sixth active pattern 36 may be connected through the fourth bridge portion 64, and the eighth active pattern 38 and the ninth active pattern 39 may be connected through the sixth bridge portion 66, thereby simultaneously reducing the connection resistance between the first active pattern 32 and the second active pattern 32, the connection resistance between the fifth active pattern 35 and the sixth active pattern 36, and the connection resistance between the eighth active pattern 38 and the ninth active pattern 39, improving the transmission efficiency of the electrical signal between the above active patterns 3, reducing the power consumption of the display substrate 100, and reducing the risk of electrostatic breakdown.

In this embodiment, the structure and arrangement of the second gate conductive layer 72 of the display substrate 100 are the same as those of the second gate conductive layer in FIG. 7e, and the structure and arrangement of the first source-drain electrode layer 81 are the same as those of the first source-drain electrode layer in FIG. 7f, which will not be repeated here.

Furthermore, the sixth bridge portion 66 is also connected to the sixteenth via hole connection portion 516 of the seventh active pattern 37, so that the eighth active pattern 38, the ninth active pattern 39 and the seventh active pattern 37 may be connected through the sixth bridge portion 66, thereby reducing the connection resistance between the eighth active pattern 38, the ninth active pattern 39 and the seventh active pattern 37, improving the transmission efficiency of the electrical signal between the above active patterns 3, reducing the power consumption of the display substrate 100, and reducing the risk of electrostatic breakdown.

### Eighth Possible Embodiment

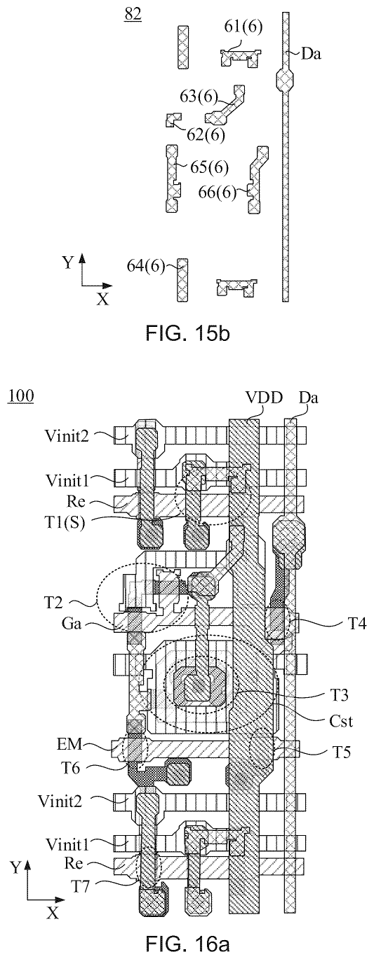

As shown in FIG. 15a, FIG. 15a is a structural diagram of a display substrate 100 in this embodiment. As shown in FIG. 15b, FIG. 15b is a structural diagram of the second source-drain electrode layer 82 in the display substrate 100 shown in FIG. 15a. The plurality of bridge portions 6 in the display substrate 100 include the first bridge portion 61, the second bridge portion 62, the third bridge portion 63, the fourth bridge portion 64, the fifth bridge portion 65 and the sixth bridge portion 66 located in the second source-drain electrode layer 82. For the first bridge portion 61, the second bridge portion 62, the third bridge portion 63, the fourth bridge portion 64, the fifth bridge portion 65 and the sixth bridge portion 66, their arrangement and beneficial effects are the same as those of the bridge portions in FIG. 7c, which will not be repeated here. The second source-drain electrode layer 82 further includes the plurality of data lines Da extending along the second direction Y and arranged at intervals in sequence along the first direction X.

In this embodiment, the structure and arrangement of the semiconductor layer 2 of the display substrate 100 are the same as those of the semiconductor layer in FIG. 7b, the structure and arrangement of the first gate conductive layer 71 of the display substrate 100 are the same as those of the first gate conductive layer in FIG. 12c, the structure and arrangement of the second gate conductive layer 72 are the same as those of the second gate conductive layer in FIG. 7e, and the structure and arrangement of the first source-drain electrode layer 81 are the same as those of the first source-drain electrode layer in FIG. 7f, which will not be repeated here.

### Ninth Possible Embodiment

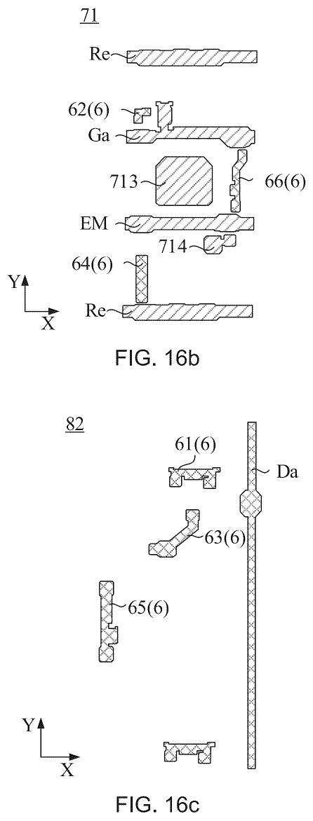

As shown in FIG. 16a, FIG. 16a is a structural diagram of a display substrate 100 in this embodiment. As shown in FIG. 16b, FIG. 16b is a structural diagram of the first gate conductive layer 71 in the display substrate 100 shown in FIG. 16a. The plurality of bridge portions 6 in the display substrate 100 include the second bridge portion 62, the fourth bridge portion 64, and the sixth bridge portion 66 located in the first gate conductive layer 71. The first gate conductive layer 71 further includes: the reset signal line Re, the gate line Ga, the first electrode plate 713, the enable signal line EM, and the third connection pattern 714 arranged at intervals in sequence along the second direction Y.

As shown in FIG. 16c, FIG. 16c is a structural diagram of the second source-drain electrode layer 82 in the display substrate 100 shown in FIG. 16a. The plurality of bridge portions 6 in the display substrate 100 further include the first bridge portion 61, the third bridge portion 63 and the fifth bridge portion 65 located in the second source-drain electrode layer 82. The second source-drain electrode layer 82 further includes the plurality of data lines Da extending along the second direction Y and arranged at intervals in sequence along the first direction X.

For the first bridge portion 61, the second bridge portion 62, the third bridge portion 63, the fourth bridge portion 64, the fifth bridge portion 65 and the sixth bridge portion 66, their arrangement and beneficial effects are the same as those of the bridge portions in FIG. 7c, which will not be repeated here.

In this embodiment, the structure and arrangement of the semiconductor layer 2 of the display substrate 100 are the same as those of the semiconductor layer in FIG. 7b, the structure and arrangement of the second gate conductive layer 72 of the display substrate 100 are the same as those of the second gate conductive layer in FIG. 7e, and the structure and arrangement of the first source-drain electrode layer 81 are the same as those of the first source-drain electrode layer in FIG. 7f, which will not be repeated here.

In some embodiments, in a case where a bridge portion 6 is located in the second source-drain electrode layer 82, the bridge portion 6 includes first bridge sub-portion(s) and second bridge sub-portion(s) that are connected. The first bridge sub-portion is located in the first gate conductive layer 71, and the second bridge sub-portion is located in the second source-drain electrode layer 82.

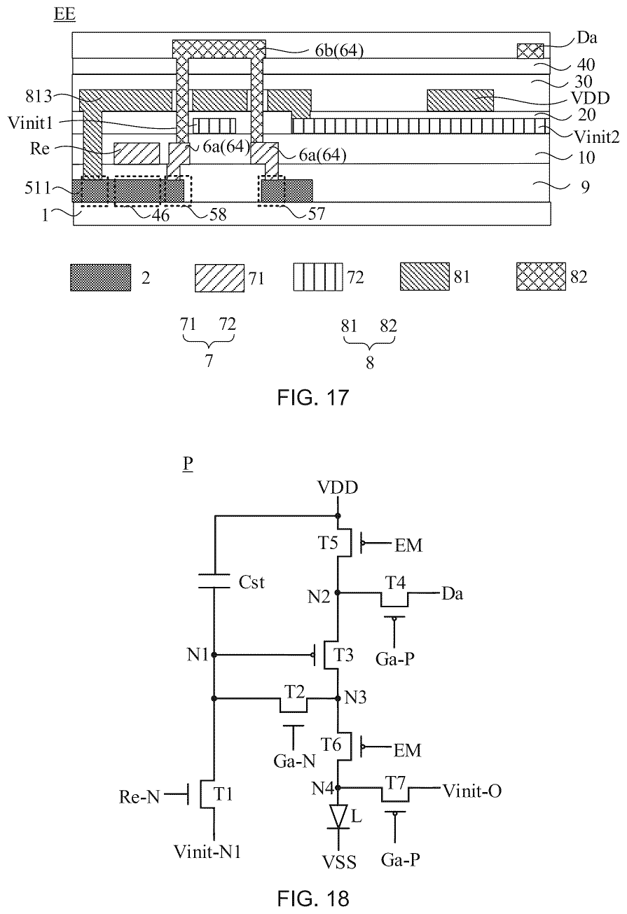

For example, as shown in FIG. 17, FIG. 17 is another sectional view of the display substrate 100 shown in FIG. 12a taken along the direction EE, a bridge portion 6 includes first bridge sub-portion(s) 6a and second bridge sub-portion(s) 6b that are connected. The fourth bridge portion 64 includes two first bridge sub-portions 6a and one second bridge sub-portion 6b, and the second bridge sub-portion 6b is connected to the two first bridge sub-portions 6a. One of the two first bridge sub-portions 6a is connected to the eighth via hole connection portion 58, and the other first bridge sub-portion 6a is connected to the seventh via hole connection portion 57, so that the fourth bridge portion 64 is connected to the seventh via hole connection portion 57 and the eighth via hole connection portion 58.

In some embodiments, as shown in FIG. 17, a first gate insulating layer 9 is provided between the semiconductor layer 2 and the first gate conductive layer 71; a second gate insulating layer 10 is provided between first gate conductive layer 71 and the second gate conductive layer 72; an interlayer dielectric layer 20 is provided between the second gate conductive layer 72 and the first source-drain electrode layer 81; and a passivation layer 30 and a planarization layer 40 are provided between the first source-drain electrode layer 81 and the second source-drain electrode layer 82. The first gate insulating layer 9 is used to insulate the semiconductor layer 2 from the first gate conductive layer 71 to prevent short circuit; the second gate insulating layer 10 is used to insulate the first gate conductive layer 71 from the second gate conductive layer 72 to prevent short circuit; the interlayer dielectric layer 20 is used to insulate the second gate conductive layer 72 from the first source-drain electrode layer 81 to prevent short circuit; and the passivation layer 30 and the planarization layer 40 are used to insulate the first source-drain electrode layer 81 from the second source-drain electrode layer 82 to prevent short circuit.

For example, in a case where a bridge portion 6 is located in the first gate conductive layer 71, the bridge portion 6 needs to be connected to a via hole connection portion 5 through a via hole penetrating at least the first gate insulating layer 9. In a case where a bridge portion 6 is located in the second source-drain electrode layer 82, the bridge portion 6 needs to be connected to a via hole connection portion 5 through a via hole penetrating at least the first gate insulating layer 9, the second gate insulating layer 10, the interlayer dielectric layer 20, the passivation layer 30, and the planarization layer 40. In a case where a bridge portion 6 includes a first bridge sub-portion 6a and a second bridge sub-portion 6b that are connected, the first bridge sub-portion 6a is located in the first gate conductive layer 71, and the second bridge sub-portion 6b is located in the second source-drain electrode layer 82, the first bridge sub-portion 6a needs to be connected to a via hole connection portion 5 through a via hole penetrating at least the first gate insulating layer 9, and the second bridge sub-portion 6b needs to be connected to the via hole connection portion 5 through a via hole penetrating at least the second gate insulating layer 10, the interlayer dielectric layer 20, the passivation layer 30, and the planarization layer 40.

The above embodiments are described by taking an example in which the transistors in the display substrate 100 are low temperature polysilicon (LTPS) transistors. It can be understood that the transistors in the pixel driving circuit P in the display substrate 100 may include low temperature polycrystalline oxide (LTPO) transistor(s).

As shown in FIG. 18, FIG. 18 is an equivalent circuit diagram of the “7T1C” structure in the case where the transistors in the pixel driving circuit P include low temperature polycrystalline oxide transistors. The transistors in the pixel driving circuit P include: a first reset transistor T1, a compensation transistor T2, a driving transistor T3, a switching transistor T4, a second light-emitting control transistor T5, a first light-emitting control transistor T6, a second reset transistor T7 and a storage capacitor Cst. The first reset transistor T1 and the compensation transistor T2 are low temperature polycrystalline oxide transistors, which may reduce leakage currents of the first reset transistor T1 and the compensation transistor T2. The driving transistor T3, the switching transistor T4, and the second light-emitting control transistor T5, the first light-emitting control transistor T6, and the second reset transistor T7 are low temperature polycrystalline oxide transistors, which may maintain strong driving capabilities of the driving transistor T3, the switching transistor T4, the second light-emitting control transistor T5, the first light-emitting control transistor T6, and the second reset transistor T7.

In some examples, in the pixel driving circuit P shown in FIG. 18, the first reset transistor T1 and the compensation transistor T2 are N-type transistors; and the driving transistor T3, the switching transistor T4, the second light-emitting control transistor T5, the first light-emitting control transistor T6, and the second reset transistor T7 are P-type transistors.

It can be understood that, in the working process of the pixel driving circuit P, a variety of signal lines are required to provide respective electrical signals. Based on this, for example, the display substrate 100 further includes: a first reset signal line Re-N for providing a first reset signal, a third initial signal line Vinit-N1 for providing a third initial signal, a fourth initial signal line Vinit-O for providing a fourth initial signal, an enable signal line EM for providing an enable signal, a first gate line Ga-P for providing a first gate signal, a second gate line Ga-N for providing a second gate signal, a power supply voltage signal line VDD for providing a power supply voltage signal, and a data line Da for providing a data signal.

In some examples, a gate of the first reset transistor T1 is electrically connected to the first reset signal line Re-N, a first electrode of the first reset transistor T1 is electrically connected to the third initial signal line Vinit-N1, and a second electrode of the first reset transistor T1 is electrically connected to a first node N1.

For example, the first reset transistor T1 is configured to be turned on under control of the first reset signal transmitted by the first reset signal line Re-N, and transmit the third initial signal received at the third initial signal line Vinit-N1 to the first node N1, so as to reset the first node N1.

In some examples, a gate of the second reset transistor T7 is electrically connected to the first gate line Ga-P, a first electrode of the second reset transistor T7 is electrically connected to the fourth initial signal line Vinit-O, and a second electrode of the second reset transistor T7 is electrically connected to a fourth node N4.

For example, the second reset transistor T7 is configured to be turned on under control of the first gate signal transmitted by the first gate line Ga-P, and transmit the fourth initial signal received at the fourth initial signal line Vinit-O to the fourth node N4, so as to reset the fourth node N4.

In some examples, a gate of the switching transistor T4 is electrically connected to the first gate line Ga-P, a first electrode of the switching transistor T4 is electrically connected to the data line Da, and a second electrode of the switching transistor T4 is electrically connected to a second node N2.

For example, the switching transistor T4 is configured to be turned on under the control of the first gate signal, and transmit the data signal received at the data line Da to the second node N2.

In some examples, a gate of the driving transistor T3 is electrically connected to the first node N1, a first electrode of the driving transistor T3 is electrically connected to the second node N2, and a second electrode of the driving transistor T3 is electrically connected to a third node N3.

For example, the driving transistor T3 is configured to be turned on under control of the voltage of the first node N1, and transmit an electrical signal (e.g., the data signal) from the second node N2 to the third node N3.

In some examples, a gate of the compensation transistor T2 is electrically connected to the second gate line Ga-N, a first electrode of the compensation transistor T2 is electrically connected to the first node N1, and a second electrode of the compensation transistor T2 is electrically connected to the third node N3.

For example, the compensation transistor T2 is configured to be turned on under control of the second gate signal, and transmit the electrical signal (e.g., the data signal) from the third node N3 to the first node N1.

In some examples, a gate of the second light-emitting control transistor T5 is electrically connected to the enable signal line EM, a first electrode of the second light-emitting control transistor T5 is electrically connected to the power supply voltage signal line VDD, and a second electrode of the second light-emitting control transistor T5 is electrically connected to the second node N2.

For example, the second light-emitting control transistor T5 is configured to be turned on under control of the enable signal transmitted by the enable signal line EM, and transmit the power supply voltage signal received at the power supply voltage signal line VDD to the second node N2.

In some examples, a gate of the first light-emitting control transistor T6 is electrically connected to the enable signal line EM, a first electrode of the first light-emitting control transistor T6 is electrically connected to the third node N3, and a second electrode of the first light-emitting control transistor T6 is electrically connected to the fourth node N4.

For example, the first light-emitting control transistor T6 is configured to be turned on under the control of the enable signal, and transmit the electrical signal from the third node N3 to the fourth node N4.

In some examples, a first electrode of the storage capacitor Cst is electrically connected to the first node N1, and a second electrode of the storage capacitor Cst is electrically connected to the power supply voltage signal line VDD.

For example, the storage capacitor Cst is configured to maintain the voltage of the first node N1 when the first reset transistor T1 and the compensation transistor T2 are turned off.

For example, the display substrate further includes a common voltage line VSS.

For example, the light-emitting device L is electrically connected to the fourth node N4, and the light-emitting device L is further electrically connected to the common voltage line VSS. The light-emitting device L is configured to emit light under control of the electrical signal from the fourth node N4 and the common voltage signal from the common voltage line VSS.

For example, the working process of the pixel driving circuit P includes a reset phase, a data writing and compensation phase, and a light-emitting phase that are performed in sequence. For the specific working process, reference is made to, for example, the working process of the pixel driving circuit P in the above embodiments, which will not be repeated here.

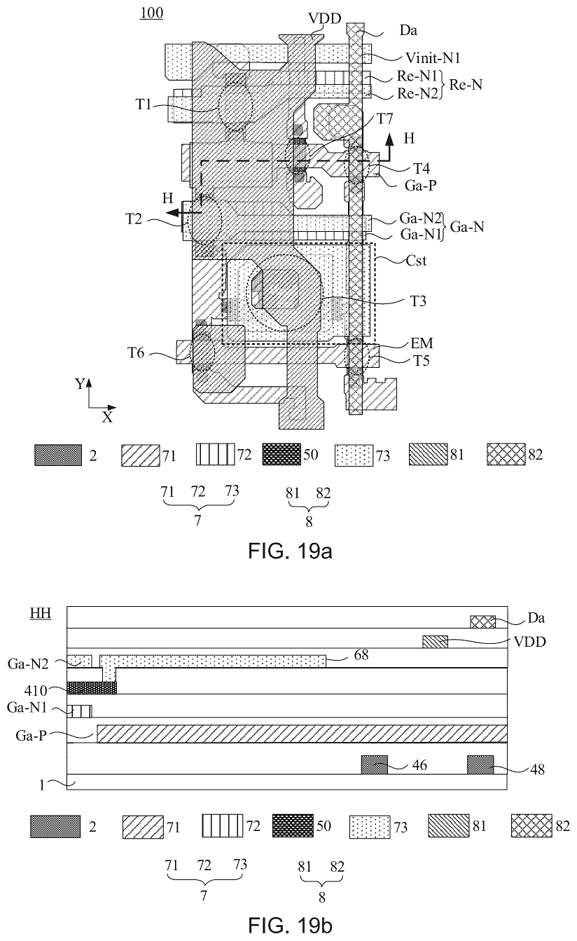

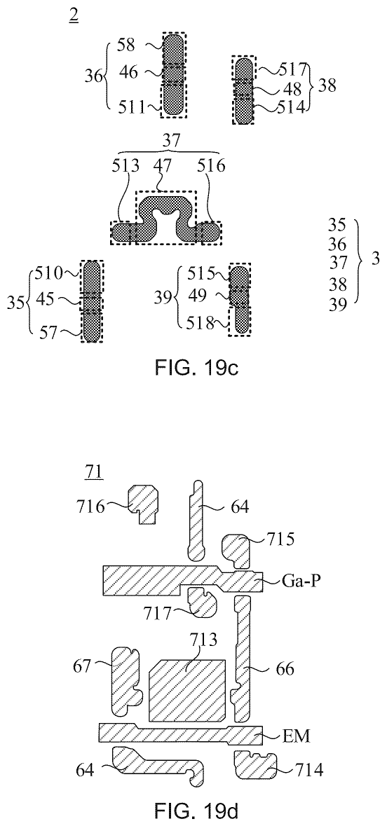

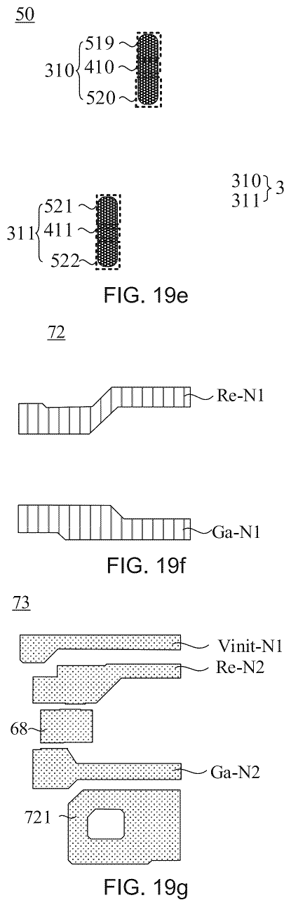

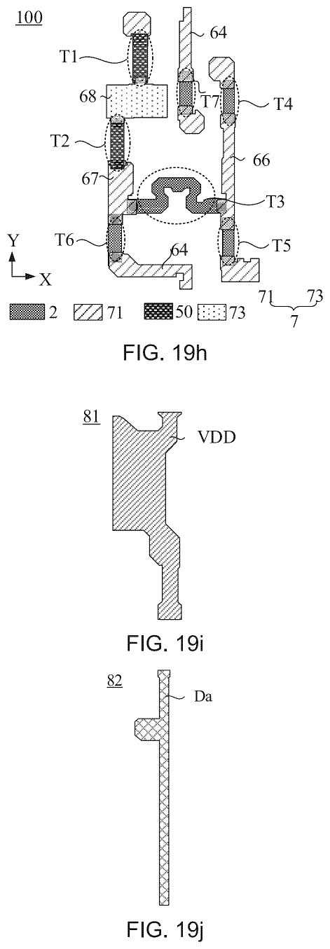

A top view structure of the pixel driving circuit P provided in FIG. 18 is introduced below. As shown in FIG. 19a, FIG. 19a is a top view of another display substrate 100 provided in embodiments of the present disclosure. In the first direction X, the first light-emitting control transistor T6 and the second light-emitting control transistor T5 are arranged in the same row, the second reset transistor T7 and the switching transistor T4 are arranged in the same row, and the second reset transistor T7 is located between the first reset transistor T1 and the switching transistor T4; in the second direction Y, the first light-emitting control transistor T6 and the compensation transistor T2 are arranged in the same column, the second light-emitting control transistor T5 and the switching transistor T4 are arranged in the same column, and the second reset transistor T7 is located between the first reset transistor T1 and the compensation transistor T2. The driving transistor T3 is located between the first light-emitting control transistor T6 and the second light-emitting control transistor T5, and located between the first light-emitting control transistor T6 and the compensation transistor T2. The driving transistor T3 overlaps the storage capacitor Cst.

As shown in FIG. 19b, FIG. 19b is a sectional view of the display substrate 100 shown in FIG. 19a taken along the direction HH. A third gate conductive layer 73 and an oxide semiconductor layer 50 are provided between the second gate conductive layer 72 and the first source-drain electrode layer 81 of the display substrate 100, and the third gate conductive layer 73 is located on a side of the oxide semiconductor layer 50 away from the substrate 1. It can be understood that, among the second gate conductive layer 72, the oxide semiconductor layer 50, the third gate conductive layer 73, and the first source-drain electrode layer 81, at least one insulating layer is provided between any two adjacent film layers, which is used to achieve insulation between the two adjacent film layers, thereby preventing short circuit.

For example, the first reset signal line Re-N includes a first reset signal sub-line Re-N1 located in the second gate conductive layer 72 and a second reset signal sub-line Re-N2 located in the third gate conductive layer 73. The same signal is input to the first reset signal sub-line Re-N1 and the second reset signal sub-line Re-N2. The second gate line Ga-N includes a first gate sub-line Ga-N1 located in the second gate conductive layer 72 and a second gate sub-line Ga-N2 located in the third gate conductive layer 73. The same signal is input to the first gate sub-line Ga-N1 and the second gate sub-line Ga-N2.

As shown in FIG. 19c, FIG. 19c is a structural diagram of the semiconductor layer 2 in the display substrate 100 shown in FIG. 19a. For the driving transistor T3, the switching transistor T4, the second light-emitting control transistor T5, the first light-emitting control transistor T6, and the second reset transistor T7, the active patterns 3 included in them and the arrangement of the active patterns 3 are the same as the active patterns 3 and the arrangement of the active patterns 3 in FIG. 7b. The arrangement of the active portion 4 and via hole connection portion 5 included in the above active pattern 3 is the same as that of the active portion 4 and the via hole connection portion 5 in FIG. 7b, which will not be repeated here.

As shown in FIG. 19d, FIG. 19d is a structural diagram of the first gate conductive layer 71 in the display substrate 100 shown in FIG. 19a. The plurality of bridge portions 6 of the display substrate 100 include the sixth bridge portion 66, the seventh bridge portion 67 and the fourth bridge portion 64, the arrangement and beneficial effects of the fourth bridge portion 64 and the sixth bridge portion 66 are the same as those of the fourth bridge portion 64 and the sixth bridge portion 66 in FIG. 7c. With reference to FIGS. 19c, 19d, and 19e, the seventh bridge portion 67 is used to connect the tenth via hole connection portion 510 of the first light-emitting control transistor T6, the thirteenth via hole connection portion 513 of the driving transistor T3, and a twenty-second via hole connection portion 522 of the compensation transistor T2.

By arranging the seventh bridge portion 67, the connection resistance between the first light-emitting control transistor T6, the driving transistor T3 and the compensation transistor T2 may be reduced, the transmission efficiency of the electrical signal between the active patterns 3 of the above transistors may be improved, the power consumption of the display substrate 100 may be reduced, and the risk of electrostatic breakdown may be reduced.

The first gate conductive layer 71 further includes a plurality of first gate lines Ga-P and a plurality of enable signal lines EM that extend along the first direction X and are arranged at intervals in sequence along the second direction Y.

The first gate conductive layer 71 further includes a first electrode plate 713, a third connection pattern 714, an eighth connection pattern 715, a ninth connection pattern 716, and a tenth connection pattern 717. The first electrode plate 713 and the third connection pattern 714 are arranged in the same manner as in FIG. 7c, which will not be repeated here. The eighth connection pattern 715 is used to electrically connect the seventeenth via hole connection portion 517 of the switching transistor T4 to the data line Da described below, the ninth connection pattern 716 is used to electrically connect a nineteenth via hole connection portion 519 of the first reset transistor T1 to the third initial signal line Vinit-N1, and the tenth connection pattern 717 is used to electrically connect the eleventh via hole connection portion 511 of the second reset transistor T7 to the fourth initial signal line Vinit-O.

In some examples, as shown in FIG. 19d, the distance between the fourth bridge portion 64 and the tenth connection pattern 717 is 1.5 times to 2.5 times the size of the portion of the first gate line Ga-P located between the fourth bridge portion 64 and the tenth connection pattern 717. In this way, it may be possible to avoid short circuit caused by too small distances between the first gate line Ga-P and the fourth bridge portion 64 and between the first gate line Ga-P and the tenth connection pattern 717, and it may also be possible to avoid electrostatic breakdown between the first gate line Ga-P and the fourth bridge portion 64 and between the first gate line Ga-P and the tenth connection pattern 717 due to static electricity accumulation. Furthermore, ends of the fourth bridge portion 64 and the tenth connection pattern 717 are chamfered or rounded, which may reduce the accumulation of static electricity at the ends of the fourth bridge portion 64 and the tenth connection pattern 717, and avoid the occurrence of electrostatic breakdown.

In some examples, arrangements between the sixth bridge portion 66 and the eighth connection pattern 715, between the sixth bridge portion 66 and the third connection pattern 714, and between the seventh bridge portion 67 and the fourth connection pattern 64 are similar to the arrangement between the fourth bridge portion 64 and the tenth connection pattern 717, which will not be repeated here.

As shown in FIG. 19e, FIG. 19e is a structural diagram of the oxide semiconductor layer 50 in the display substrate 100 shown in FIG. 19a. The active pattern corresponding to the first reset transistor T1 is a tenth active pattern 310. The tenth active pattern 310 includes a tenth active portion 410, and the nineteenth via hole connection portion 519 and a twentieth via hole connection portion 520 that are connected to the tenth active portion 410. The tenth active portion 410 is used to form the channel of the first reset transistor T1. The nineteenth via hole connection portion 519 is located at one end of the tenth active portion 410, and the twentieth via hole connection portion 520 is located at the other end of the tenth active portion 410. The active pattern corresponding to the compensation transistor T2 is an eleventh active pattern 311. The eleventh active pattern 311 includes an eleventh active portion 411, and a twenty-first via hole connection portion 521 and the twenty-second via hole connection portion 522 that are connected thereto. The eleventh active portion 411 is used to form the channel of the compensation transistor T2. The twenty-first via hole connection portion 521 is located at one end of the eleventh active portion 411, and the twenty-second via hole connection portion 522 is located at the other end of the eleventh active portion 411.

As shown in FIG. 19f, FIG. 19f is a structural diagram of the second gate conductive layer 72 in the display substrate 100 shown in FIG. 19a. The second gate conductive layer 72 includes a plurality of first reset signal sub-lines Re-N1 and a plurality of first gate sub-lines Ga-N1 that extend along the first direction X and are arranged at intervals in sequence along the second direction Y.

As shown in FIG. 19g, FIG. 19g is a structural diagram of the third gate conductive layer 73 in the display substrate 100 shown in FIG. 19a. The third gate conductive layer 73 includes a plurality of third initial signal lines Vinit-N1, a plurality of second reset signal sub-lines Re-N2, and a plurality of second gate sub-lines Ga-N2 that extend along the first direction X and arranged at intervals in sequence along the second direction Y. The third gate conductive layer 73 further includes an eighth bridge portion 68 and a second electrode plate 721. The eighth bridge portion 68 is used to connect the twentieth via hole connection portion 520 of the first reset transistor T1 and the twenty-second via hole connection portion 522 of the compensation transistor T2.

By arranging the eighth bridge portion 68, the connection resistance between the first reset transistor T1 and the compensation transistor T2 may be reduced, the transmission efficiency of the electrical signal between the active patterns 3 of the above transistors may be improved, the power consumption of the display substrate 100 may be reduced, and the risk of electrostatic breakdown may be reduced.

As shown in FIG. 19h, FIG. 19h is a structural diagram of some film layers in the display substrate 100 shown in FIG. 19a. FIG. 19h shows a structural diagram in which the fourth bridge portion 64, the sixth bridge portion 66, and the seventh bridge portion 67 are connected to the active patterns 3 of transistors.

As shown in FIG. 19i, FIG. 19i is a structural diagram of a first source-drain electrode layer 81 in the display substrate 100 shown in FIG. 19a. The first source-drain electrode layer 81 includes a power supply voltage signal line VDD extending along the second direction.

For example, as shown in FIG. 19i, an orthographic projection of the power supply voltage signal line VDD on the substrate 1 overlaps an orthographic projection of the eighth bridge portion 68 on the substrate 1. The power supply voltage signal line VDD may shield electromagnetic signals in a thickness direction of the display substrate 100, so that the stability of the electrical signal transmitted on the eighth bridge portion 68 may be maintained.

For example, the power supply voltage signal line VDD is also electrically connected to the second electrode plate 721 of the storage capacitor Cst.

As shown in FIG. 19j, FIG. 19j is a structural diagram of a second source-drain electrode layer 82 in the display substrate 100 shown in FIG. 19a. The second source-drain electrode layer 82 includes a data line Da extending along the second direction.

For example, the data line Da is electrically connected to the eighth connection pattern 715 through a via hole.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

1. A display substrate, comprising a plurality of transistors, and the plurality of transistors including dual-gate transistors, wherein the display substrate further comprises:
a substrate;
a semiconductor layer located on a side of the substrate, wherein the semiconductor layer includes a plurality of active patterns arranged at intervals; at least one active pattern includes an active portion and at least one via hole connection portion that are connected, and a via hole connection portion is located at an end of the active portion; the active portion corresponds to a transistor in the plurality of transistors, and is used to form a channel of the corresponding transistor; and
a plurality of bridge portions located on a side of the semiconductor layer away from the substrate, wherein each of the plurality of bridge portions connects via hole connection portions in different active patterns;
wherein a dual-gate transistor in the dual-gate transistors corresponds to two active patterns, and abridge portion in the plurality of bridge portions is connected to via hole connection portions in the two active patterns; a resistivity of a material of the bridge portion is less than that of a material of the semiconductor layer.

2. The display substrate according to claim 1, wherein the display substrate comprises a plurality of pixel driving circuits arranged in columns in a first direction and arranged in rows in a second direction, wherein
each pixel driving circuit includes transistors, and the transistors in the pixel driving circuit include at least one dual-gate transistor in the dual-gate transistors.

3. The display substrate according to claim 2, further comprising at least one gate conductive layer and at least one source-drain electrode layer that are located on the side of the semiconductor layer away from the substrate and are stacked in sequence;
the bridge portion is located in a target layer, and the target layer is any layer among the at least one gate conductive layer and the at least one source-drain electrode layer.

4. The display substrate according to claim 3, wherein the at least one dual-gate transistor includes a first reset transistor;
two active patterns corresponding to the first reset transistor are a first active pattern and a second active pattern, respectively; the first active pattern and the second active pattern are arranged at an interval in sequence along the first direction and extend along the second direction;
the first active pattern includes a first active portion and a first via hole connection portion that are connected, and the first active portion is used to form a channel of the first reset transistor; the second active pattern includes a second active portion and a second via hole connection portion that are connected, and the second active portion is used to form another channel of the first reset transistor;
the first via hole connection portion and the second via hole connection portion are arranged in a row along the first direction; and
the plurality of bridge portions include a first bridge portion extending along the first direction, and the first bridge portion connects the first via hole connection portion and the second via hole connection portion.

5. The display substrate according to claim 3, wherein the at least one dual-gate transistor includes a compensation transistor;
two active patterns corresponding to the compensation transistor are a third active pattern and a fourth active pattern, respectively; the third active pattern extends along the first direction, the fourth active pattern extends in the second direction, and extension lines of the third active pattern and the fourth active pattern have an intersection point;
the third active pattern includes a third active portion and a third via hole connection portion that are connected; the third via hole connection portion is located at an end of the third active portion close to the intersection point, and the third active portion is used to form a channel of the compensation transistor; the fourth active pattern includes a fourth active portion and a fourth via hole connection portion that are connected; the fourth via hole connection portion is located at an end of the fourth active portion close to the intersection point, and the fourth active portion is used to form another channel of the compensation transistor; and
the plurality of bridge portions include a second bridge portion, and the second bridge portion connects the third via hole connection portion and the fourth via hole connection portion.

6. The display substrate according to claim 4, wherein the at least one dual-gate transistor includes the first reset transistor and a compensation transistor;
two active patterns corresponding to the compensation transistor are a third active pattern and a fourth active pattern, respectively; the third active pattern extends along the first direction, the fourth active pattern extends in the second direction, and extension lines of the third active pattern and the fourth active pattern have an intersection point;
the third active pattern includes a third active portion and a third via hole connection portion that are connected; the third via hole connection portion is located at an end of the third active portion close to the intersection point, and the third active portion is used to form a channel of the compensation transistor; the fourth active pattern includes a fourth active portion and a fourth via hole connection portion that are connected; the fourth via hole connection portion is located at an end of the fourth active portion close to the intersection point, and the fourth active portion is used to form another channel of the compensation transistor; the plurality of bridge portions further include a second bridge portion, and the second bridge portion connects the third via hole connection portion and the fourth via hole connection portion;
the second active pattern further includes a fifth via hole connection portion connected to the second active portion, and the fifth via hole connection portion is located at an end of the second active portion away from the second via hole connection portion;
the third active pattern corresponding to the compensation transistor further includes a sixth via hole connection portion connected to the third active portion, and the sixth via hole connection portion is located at an end of the third active portion away from the third via hole connection portion; and
the plurality of bridge portions further include a third bridge portion, and the third bridge portion is connected to the fifth via hole connection portion and the sixth via hole connection portion.

7. The display substrate according to claim 6, wherein
in the first direction, the third active portion is located between the fourth active portion of the compensation transistor and the first active portion, and the second active portion is located on a side of the first active portion away from the third active portion;
in the second direction, the third active portion is located between the fourth active portion and the first active portion; and
an included angle between an extension direction of the third bridge portion and the first direction is an acute angle.

8. The display substrate according to claim 4, wherein the transistors in the pixel driving circuit further include a first light-emitting control transistor and a second reset transistor;
the plurality of active patterns further include a fifth active pattern and a sixth active pattern; both the fifth active pattern and the sixth active pattern extend along the second direction, and are arranged at an interval in sequence along the second direction;
the fifth active pattern includes a fifth active portion and a seventh via hole connection portion that are connected, the seventh via hole connection portion is located at an end of the fifth active portion close to a sixth active portion, and the fifth active portion is used to form a channel of the first light-emitting control transistor; the sixth active pattern includes the sixth active portion and an eighth via hole connection portion that are connected, the eighth via hole connection portion is located at an end of the sixth active portion close to the fifth active portion, and the sixth active portion is used to form a channel of the second reset transistor; and
the plurality of bridge portions further include a fourth bridge portion extending along the second direction, and the fourth bridge portion is connected to the seventh via hole connection portion and the eighth via hole connection portion.

9. The display substrate according to claim 8, wherein the at least one dual-gate transistor further includes a compensation transistor;
two active patterns corresponding to the compensation transistor are a third active pattern and a fourth active pattern, respectively; the third active pattern extends along the first direction, the fourth active pattern extends in the second direction, and extension lines of the third active pattern and the fourth active pattern have an intersection point;
the third active pattern includes a third active portion and a third via hole connection portion that are connected; the third via hole connection portion is located at an end of the third active portion close to the intersection point, and the third active portion is used to form a channel of the compensation transistor; the fourth active pattern includes a fourth active portion and a fourth via hole connection portion that are connected; the fourth via hole connection portion is located at an end of the fourth active portion close to the intersection point, and the fourth active portion is used to form another channel of the compensation transistor; the plurality of bridge portions further include a second bridge portion, and the second bridge portion connects the third via hole connection portion and the fourth via hole connection portion; and
the fifth active pattern, the sixth active pattern and the fourth active pattern are arranged at intervals in sequence along the second direction, and the fifth active pattern is connected to the fourth active pattern.

10. The display substrate according to claim 9, wherein
the fourth active pattern further includes a ninth via hole connection portion connected to the fourth active portion, and the ninth via hole connection portion is located at an end of the fourth active portion close to the fifth active portion;
the fifth active pattern further includes a tenth via hole connection portion connected to the fifth active portion, and the tenth via hole connection portion is located at an end of the fifth active portion close to the fourth active portion;
the plurality of bridge portions further include a fifth bridge portion extending along the second direction, and the fifth bridge portion connects the ninth via hole connection portion and the tenth via hole connection portion.

11. The display substrate according to claim 8, wherein the sixth active pattern corresponding to the second reset transistor in a pixel driving circuit in an i-th row and j-th column, and the first active pattern and the second active pattern corresponding to the first reset transistor in a pixel driving circuit in an (i+1)-th row and j-th column are arranged at intervals in sequence along the first direction, where i and j are both positive integers;
the at least one gate conductive layer includes a plurality of reset signal lines extending along the first direction and arranged at intervals in sequence along the second direction; and
a reset signal line in the plurality of reset signal lines covers the sixth active portion of the sixth active pattern corresponding to the second reset transistor in the pixel driving circuit in the i-th row and j-th column, and the first active portion of the first active pattern and the second active portion of the second active pattern corresponding to the first reset transistor in the pixel driving circuit in the (i+1)-th row and j-th column.

12. The display substrate according to claim 11, wherein the sixth active pattern further includes an eleventh via hole connection portion connected to the sixth active portion, and the eleventh via hole connection portion is located at an end of the sixth active portion away from the eighth via hole connection portion; the first active pattern further includes a twelfth via hole connection portion connected to the first active portion, and the twelfth via hole connection portion is located at an end of the first active portion away from the first via hole connection portion;
the at least one gate conductive layer further includes a plurality of first initial signal lines and a plurality of second initial signal lines extending along the first direction and arranged at intervals in sequence along the second direction, and the plurality of first initial signal lines and the plurality of second initial signal lines are arranged alternately;
a first initial signal line in the plurality of first initial signal lines is connected to twelfth via hole connection portions of first active patterns corresponding to first reset transistors in pixel driving circuits in an i-th row; and
a second initial signal line in the plurality of second initial signal lines is connected to eleventh via hole connection portions of sixth active patterns corresponding to second reset transistors in the pixel driving circuits in the i-th row.

13. The display substrate according to claim 12, wherein
the at least one gate conductive layer includes two gate conductive layers, and the two gate conductive layers are a first gate conductive layer adjacent to the semiconductor layer and a second gate conductive layer located on a side of the first gate conductive layer away from the semiconductor layer; and
the reset signal line is located in the first gate conductive layer, and the first initial signal line and the second initial signal line are located in the second gate conductive layer.

14. The display substrate according to claim 10, wherein the transistors in the pixel driving circuit further include a driving transistor;
the plurality of active patterns further include a seventh active pattern, and a shape of the seventh active pattern is curved; the seventh active pattern and the fourth active pattern are located on a same side of the fifth active pattern along the first direction, and the seventh active pattern is located between the fourth active pattern and the fifth active pattern along the second direction;
the seventh active pattern includes a seventh active portion and a thirteenth via hole connection portion that are connected; the thirteenth via hole connection portion is located at an end of the seventh active portion close to the fifth active portion, and the seventh active portion is used to form a channel of the driving transistor;
the fifth bridge portion is further connected to the thirteenth via hole connection portion.

15. The display substrate according to claim 14, wherein the transistors in the pixel driving circuit further include a switching transistor and a second light-emitting control transistor;
the plurality of active patterns further include an eighth active pattern and a ninth active pattern; both the eighth active pattern and the ninth active pattern extend along the second direction, and are arranged at an interval in sequence along the second direction;
the eighth active pattern includes an eighth active portion and a fourteenth via hole connection portion that are connected, the fourteenth via hole connection portion is located at an end of the eighth active portion close to a ninth active portion, and the eighth active portion is used to form a channel of the switching transistor;
the ninth active pattern includes the ninth active portion and a fifteenth via hole connection portion that are connected, the fifteenth via hole connection portion is located at an end of the ninth active portion close to the eighth active portion, and the ninth active portion is used to form a channel of the second light-emitting control transistor;
the plurality of bridge portions further include a sixth bridge portion extending along the second direction, and the sixth bridge portion is connected to the fourteenth via hole connection portion and the fifteenth via hole connection portion.

16. The display substrate according to claim 15, wherein
the seventh active pattern corresponding to the driving transistor further includes a sixteenth via hole connection portion connected to the seventh active portion, and the sixteenth via hole connection portion is located at an end of the seventh active portion close to the ninth active portion; and
the sixteenth via hole connection portion is further connected to the sixth bridge portion.

17. (canceled)

18. The display substrate according to claim wherein
the at least one gate conductive layer includes a plurality of enable signal lines and a plurality of gate lines extending along the first direction and arranged at intervals in sequence along the second direction, and the plurality of enable signal lines and the plurality of gate lines are arranged alternately;
an enable signal line in the plurality of enable signal lines covers fifth active portions corresponding to first light-emitting control transistors in pixel driving circuits in an i-th row, and ninth active portions corresponding to second light-emitting control transistors in the pixel driving circuits in the i-th row; and
a gate line in the plurality of gate lines covers third active portions and fourth active portions corresponding to compensation transistors in the pixel driving circuits in the i-th row, and eighth active portions corresponding to switching transistors in the pixel driving circuits in the i-th row, wherein
N is a positive integer.

19. The display substrate according to claim 18, wherein
the at least one gate conductive layer includes two gate conductive layers, and the two gate conductive layers are a first gate conductive layer adjacent to the semiconductor layer and a second gate conductive layer located on a side of the first gate conductive layer away from the semiconductor layer; and
the enable signal line and the gate line are both located in the first gate conductive layer.

20. (canceled)

21. (canceled)

22. The display substrate according to claim 15, wherein
the eighth active pattern further includes a seventeenth via hole connection portion connected to the eighth active portion, and the seventeenth via hole connection portion is located at an end of the eighth active portion away from the fourteenth via hole connection portion; the ninth active pattern further includes an eighteenth via hole connection portion connected to the ninth active portion, and the eighteenth via hole connection portion is located at an end of the ninth active portion away from the fifteenth via hole connection portion;
the at least one source-drain electrode layer includes two source-drain electrode layers, and the two source-drain electrode layers are a first source-drain electrode layer and a second source-drain electrode layer located on a side of the first source-drain electrode layer away from the semiconductor layer;
the first source-drain electrode layer includes a plurality of power supply voltage signal lines extending along the second direction and arranged at intervals in sequence along the first direction; the second source-drain electrode layer includes a plurality of data lines extending along the second direction and arranged at intervals in sequence along the first direction; and the plurality of power supply voltage signal lines and the plurality of data lines are arranged alternately;
a power supply voltage signal line in the plurality of power supply voltage signal lines overlaps pixel driving circuits in a j-th column, and the power supply voltage signal line is electrically connected to eighteenth via hole connection portions of ninth active patterns corresponding to second light-emitting control transistors in pixel driving circuits in the j-th column; and
a data line in the plurality of data lines is located between two adjacent columns of pixel driving circuits, and the data line is electrically connected to seventeenth via hole connection portions of eighth active patterns corresponding to switching transistors in the pixel driving circuits in the j-th column, wherein
j is a positive integer.

23-25. (canceled)

26. A display apparatus, comprising the display substrate according to claim 1.
